(19) United States
(12) Patent Application Publication
(10) Pub. No.: US 2026/0212810 A1
(43) Pub. Date: Jul. 23, 2026

(54) DISPLAY DEVICE AND ELECTRONIC DEVICE INCLUDING THE SAME

(71) Applicant: Samsung Display Co., LTD., Yongin-si (KR)

(72) Inventors: Hosik SHIN, Yongin-si (KR); Sangwoo KIM, Yongin-si (KR); Jiyeon SEO, Yongin-si (KR); Hyungsoo YOON, Yongin-si (KR); Hyejin JOO, Yongin-si (KR); Myunghee HAN, Yongin-si (KR)

(21) Appl. No.: 19/457,685

(22) Filed: Jan. 23, 2026

(30) Foreign Application Priority Data
Jan. 23, 2025 (KR) 10-2025-0010658

(51) Int. Cl. G09G 3/32; G09G 3/3233

(52) U.S. Cl. CPC G09G 3/32; G09G 3/3233; G09G 2300/0426; G09G 2300/0819; G09G 2300/0842

(57) ABSTRACT

A display device includes a substrate having a first display area and a second display area surrounded by the first display area; a plurality of first light-emitting diodes and a plurality of first pixel driving circuits disposed in the first display area; and a gate driving circuit disposed in the second display area and providing a scan signal to the plurality of first pixel driving circuits, where a shape of the second display area in the substrate is different from a shape of the first display area, and an electronic device employing the same.

This application claims priority to Korean Patent Application No. 10-2025-0010658, filed on January 23, 2025, and all the benefits accruing therefrom under 35 U.S.C. §119, the content of which in its entirety is herein incorporated by reference.

### BACKGROUND

### 1. Field

Embodiments of the disclosure relate to a display device and an electronic device including the same.

### 2. Description of the Related Art

With the development of display devices that visually display electrical signals, various display devices having excellent characteristics, such as thinness, light weight, and low power consumption, are being introduced. For example, flexible display devices that are foldable or rollable in a roll shape are being introduced. Recently, stretchable display devices capable of being deformed into various shapes and electronic devices of various structures including the same are being actively under research and development.

### SUMMARY

Embodiments of the disclosure aim to provide a display device with relatively high reliability and an electronic device including the same.

An embodiment of the disclosure provides a display device including: a substrate having a first display area and a second display area surrounded by the first display area; a plurality of first light-emitting diodes and a plurality of first pixel driving circuits disposed in the first display area; and a gate driving circuit disposed in the second display area and providing a scan signal to the plurality of first pixel driving circuits, where a shape of the second display area in the substrate is different from a shape of the first display area.

In an embodiment, the first display area may include a plurality of first island portions separated by a plurality of first opening areas passing through the substrate, and the second display area may include one second island portion in which the substrate is continuously disposed.

In an embodiment, the substrate may further include a middle area disposed between the first display area and the second display area, the middle area may include a plurality of third island portions separated by a plurality of third opening areas passing through the substrate, and a shape of a third opening area among the plurality of third island portions may be different from a shape of a first opening area opening area among the plurality of first opening areas.

In an embodiment, the display device may further include a third light-emitting diode disposed in the middle area, where the third light-emitting diode may be connected to one of the plurality of first pixel driving circuits disposed in the first display area.

In an embodiment, the display device may further include a second light-emitting diode disposed in the second display area and a second pixel driving circuit that drives the second light-emitting diode, where the second light-emitting diode may include a second-1 light-emitting diode that overlaps the second pixel driving circuit and a second-2 light-emitting diode that overlaps the gate driving circuit.

In an embodiment, the second pixel driving circuit may be disposed closer to the first display area than the gate driving circuit.

In an embodiment, the display device may further include a plurality of scan lines connected to the gate driving circuit and transmitting the scan signal, where the plurality of scan lines may be disposed radially from the second display area to an outside of the first display area.

In an embodiment, the display device may further include a plurality of data lines crossing the plurality of scan lines, where the plurality of data lines may be disposed to surround the second display area.

In an embodiment, the plurality of data lines and the plurality of scan lines may be disposed in a curved shape.

An embodiment of the disclosure provides a display device including: a substrate including a display area having a first display area and a second display area surrounded by the first display area; a plurality of first light-emitting diodes and a plurality of first pixel driving circuits disposed in the first display area; a gate driving circuit disposed in the second display area and providing a scan signal to the plurality of first pixel driving circuits; and a plurality of second light-emitting diodes disposed in the second display area and at least partially overlapping the gate driving circuit.

In an embodiment, the second display area may be disposed in a center of the display area.

In an embodiment, the display device may further include a plurality of second pixel driving circuits disposed in the second display area and driving the plurality of second light-emitting diodes, where the plurality of second light-emitting diodes may include a plurality of second-1 light-emitting diodes that overlap the plurality of second pixel driving circuits and a plurality of second-2 light-emitting diodes that overlap the gate driving circuit.

In an embodiment, the plurality of second pixel driving circuits may be disposed closer to the first display area than the gate driving circuit.

In an embodiment, the first display area may include a plurality of first island portions separated by a plurality of first opening areas passing through the substrate, and the second display area may include one second island portion in which the substrate is continuously disposed.

In an embodiment, the display device may further include a plurality of scan lines connected to the gate driving circuit and transmitting the scan signal, where the plurality of scan lines may be disposed radially from the second display area to an outside of the first display area.

An embodiment of the disclosure provides an electronic device including a display device, where the display device includes: a substrate including a display area having a first display area and a second display area surrounded by the first display area; a plurality of first light-emitting diodes and a plurality of first pixel driving circuits disposed in the first display area; a gate driving circuit disposed in the second display area and providing a scan signal to the plurality of first pixel driving circuits; and a plurality of second light-emitting diodes disposed in the second display area and at least partially overlapping the gate driving circuit.

In an embodiment, the second display area may be disposed in a center of the display area.

In an embodiment, the electronic device may further include a plurality of second pixel driving circuits disposed in the second display area and driving the plurality of second light-emitting diodes, where the plurality of second light-emitting diodes may include a plurality of second-1 light-emitting diodes that overlap the plurality of second pixel driving circuits and a plurality of second-2 light-emitting diodes that overlap the gate driving circuit.

In an embodiment, the plurality of second pixel driving circuits may be disposed closer to the first display area than the gate driving circuit.

In an embodiment, the first display area may include a plurality of first island portions separated by a plurality of first opening areas passing through the substrate, and the second display area may include one second island portion in which the substrate is continuously disposed.

As described above, the display device and the electronic device in an embodiment of the disclosure may ensure the reliability of a display device and an electronic device because a gate driving circuit is disposed inside a display area.

### BRIEF DESCRIPTION OF DRAWINGS

The above and other embodiments, advantages and features of this disclosure will become more apparent by describing in further detail embodiments thereof with reference to the accompanying drawings.

FIG. 1 is a perspective view schematically illustrating an embodiment of a display device according to the disclosure.

FIGS. 2A and 2B are perspective views illustrating a state in which the display device of FIG. 1 is stretched in a first direction.

FIG. 2C is a perspective view illustrating a state in which the display device of FIG. 1 is stretched in a second direction.

FIG. 2D is a perspective view illustrating a state in which the display device of FIG. 1 is stretched in the first direction and the second direction.

FIG. 2E is a perspective view illustrating a state in which the display device of FIG. 1 is stretched in a third direction.

FIG. 2F is a perspective view illustrating a state in which the display device of FIG. 1 is stretched in the first direction, the second direction, and the third direction.

FIG. 3A is a plan view schematically illustrating an embodiment of a display device according to the disclosure.

FIG. 3B is a perspective view schematically illustrating an embodiment of a display device according to the disclosure.

FIG. 4 is an enlarged plan view of an embodiment of region A of FIG. 3A as a portion of a display device according to the disclosure.

FIG. 5 is a cross-sectional view schematically illustrating an embodiment of a first island portion and a first bridge portion which are disposed in a display area of a display device according to the disclosure.

FIGS. 6A to 6C are respectively equivalent circuit diagrams of an embodiment of a pixel driving circuit that may be included in a display device, according to the disclosure.

FIG. 7A is a cross-sectional view schematically illustrating an embodiment of a light-emitting element of a display device, according to the disclosure.

FIG. 7B is a cross-sectional view schematically illustrating an embodiment of a light-emitting element of a display device, according to the disclosure.

FIG. 8 is an enlarged plan view of an embodiment of region A of FIG. 3A as a portion of a display device according to the disclosure.

FIG. 9 is a cross-sectional view schematically illustrating an embodiment of a portion of a display device according to the disclosure.

FIGS. 10A and 10B are plan views illustrating an embodiment of a portion of a display device according to the disclosure.

FIG. 11A is a perspective view schematically illustrating an embodiment of an electronic device including a display device, according to the disclosure.

FIG. 11B is a block diagram schematically illustrating an embodiment of an electronic device including a display device, according to the disclosure.

FIGS. 12A to 12I are respectively perspective views schematically illustrating embodiments of an electronic device including a display device according to the disclosure.

### DETAILED DESCRIPTION

The disclosure may undergo various modifications and have various embodiments, and illustrative embodiments are illustrated in the drawings and described in detail in the detailed description. Effects and features of the disclosure, and methods of achieving them will be clarified with reference to embodiments described below in detail with reference to the drawings. However, the disclosure is not limited to embodiments disclosed below and may be embodied in various forms.

Hereinafter, embodiments of the disclosure will be described in detail with reference to the accompanying drawings, and when describing embodiments of the disclosure with reference to the drawings, the same or corresponding elements are denoted by the same reference numerals, and redundant descriptions thereof are omitted.

In the following embodiments, the terms "first," "second," etc. are not used in a restrictive sense and are used for the purpose of distinguishing one element from another.

In the following embodiments, singular expressions include plural expressions unless the context clearly indicates otherwise.

In the following embodiments, the terms "include," "comprise," etc. mean the presence of features or elements stated in the specification, but do not preclude the possibility that one or more other features or elements may be added.

In the following embodiments, when a portion, such as a film, region, or element, is referred to as being above or on another portion, not only a case where the portion is directly on the other layer but also a case where an intervening film, region, element, etc. is therebetween are included.

Sizes of elements in the drawings may be exaggerated or reduced for convenience of explanation. For example, because sizes and widths of the respective elements illustrated in the drawings are arbitrarily illustrated for convenience of explanation, the disclosure is not necessarily limited to the illustrated sizes and widths.

In the following embodiments, the x-axis, the y-axis, and the z-axis are not limited to three axes of the rectangular coordinate system and may be interpreted in a broader sense. For example, the x-axis, the y-axis, and the z-axis may be perpendicular to one another, but may represent different directions that are not perpendicular to one another.

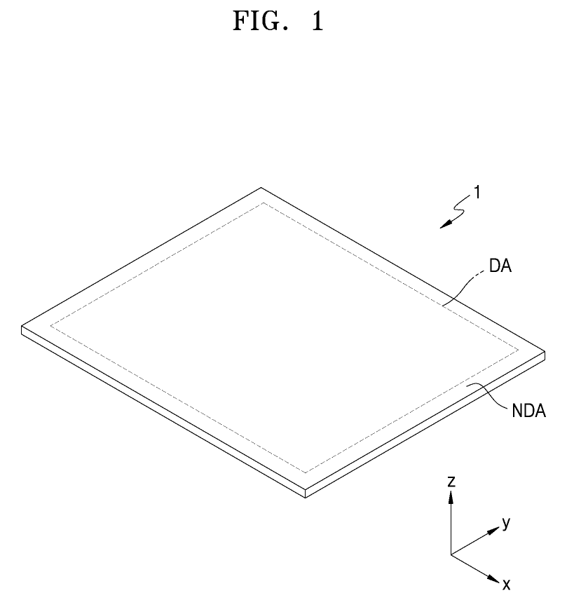

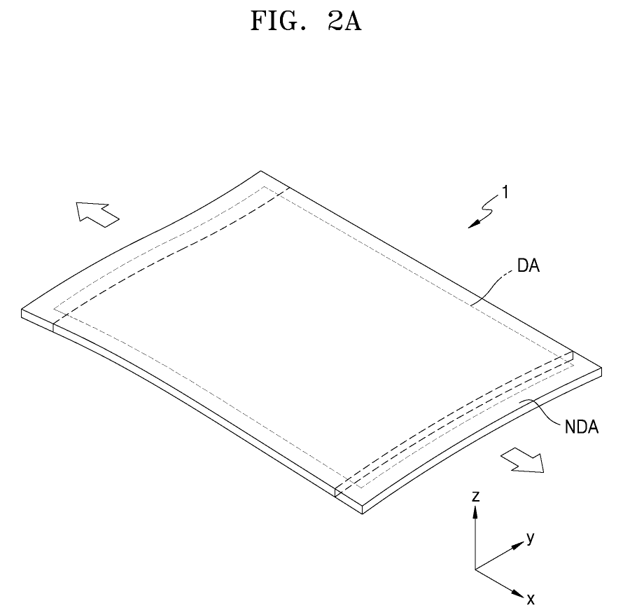

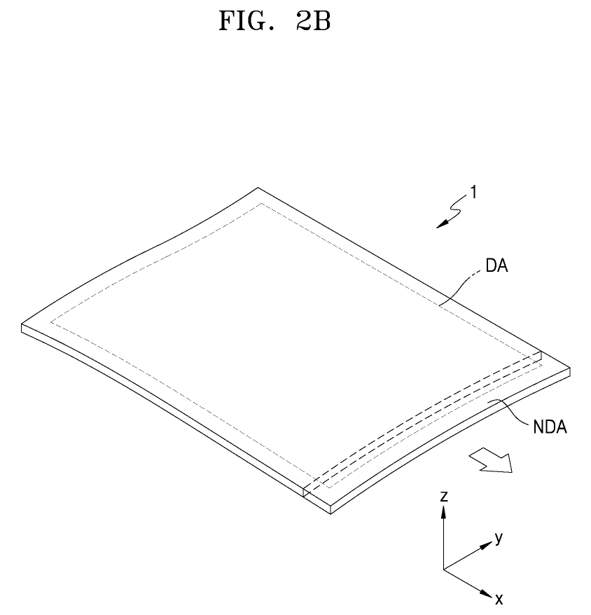

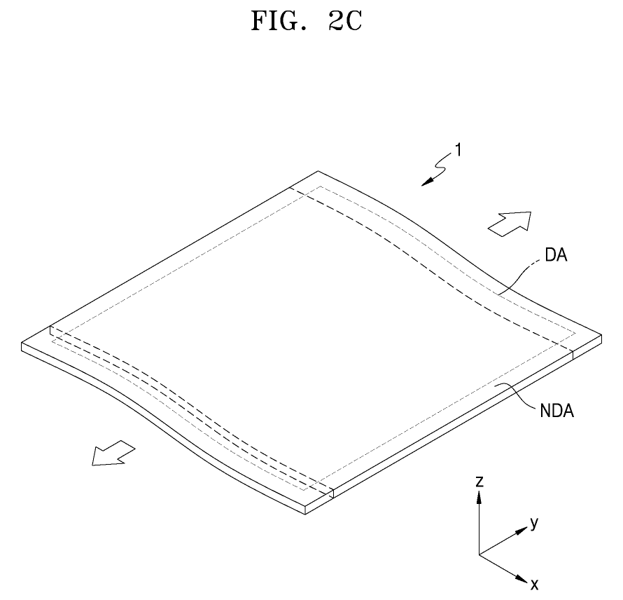

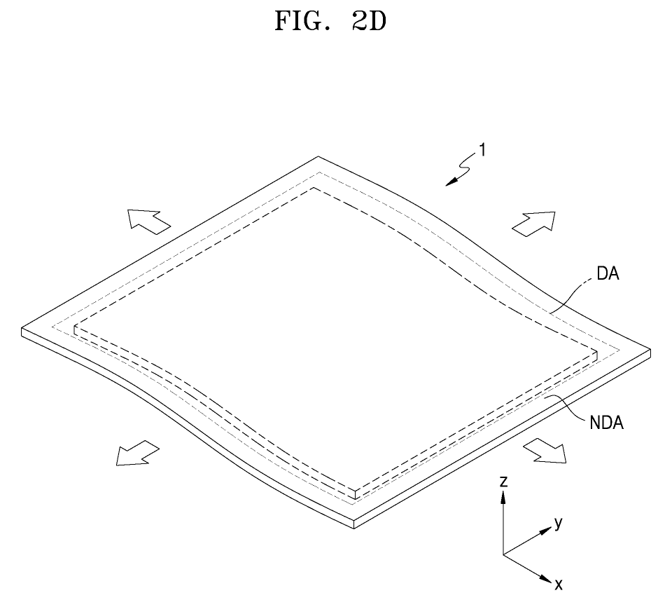

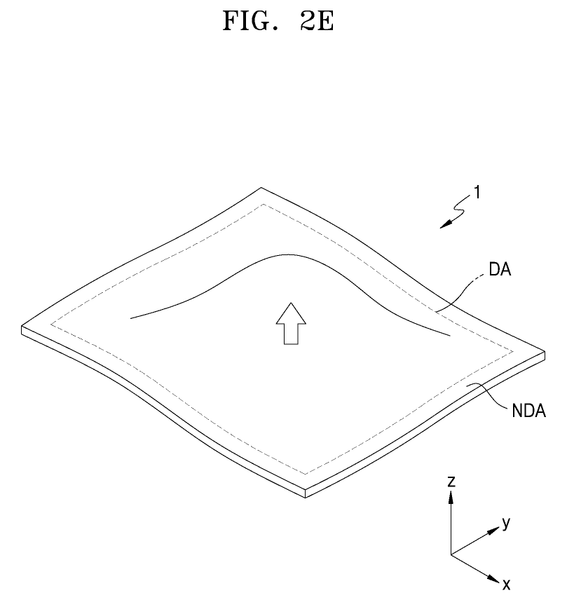

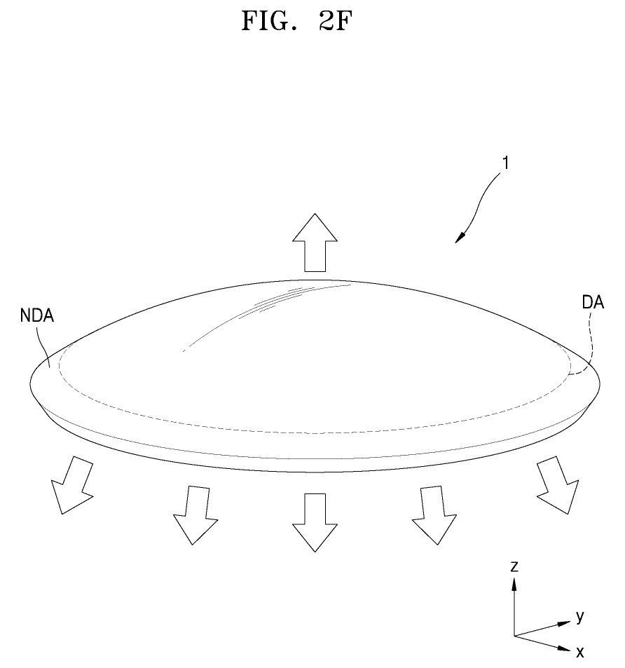

FIG. 1 is a schematic perspective view of an embodiment of a display device 1 according to the disclosure. FIGS. 2A and 2B are perspective views illustrating a state in which the display device 1 of FIG. 1 is stretched in a first direction. FIG. 2C is a perspective view illustrating a state in which the display device 1 of FIG. 1 is stretched in a second direction. FIG. 2D is a perspective view illustrating a state in which the display device 1 of FIG. 1 is stretched in the first direction and the second direction. FIG. 2E is a perspective view illustrating a state in which the display device 1 of FIG. 1 is stretched in a third direction. FIG. 2F is a perspective view illustrating a state in which the display device 1 of FIG. 1 is stretched in the first direction, the second direction, and the third direction.

Referring to FIG. 1, the display device 1 may include a display area DA and a non-display area NDA. The display area DA may include a plurality of pixels. The display device 1 may provide a predetermined image by light emitted from the plurality of pixels. The non-display area NDA may be disposed outside the display area DA. The non-display area NDA is an area in which pixels are not disposed, and may completely surround the display area DA.

The display device 1 may be stretched or contracted in various directions. The display device 1 may be stretched in the first direction (e.g., the x direction and/or the -x direction) by an external force applied by an external object or a user. In an embodiment, as illustrated in FIGS. 2A and 2B, the display area DA and/or the non-display area NDA of the display device 1 may be stretched in the first direction (e.g., the x direction and/or the -x direction). In an embodiment, as illustrated in FIG. 2A, the display device 1 may be stretched in the x direction and the -x direction, or as illustrated in FIG. 2B, the display device 1 may be stretched in the x direction while one side of the display device 1 is fixed, for example.

The display device 1 may be stretched in the second direction (e.g., the y direction and/or the -y direction) by an external force applied by an external object or a user. In an embodiment, as illustrated in FIG. 2C, the display area DA and/or the non-display area NDA of the display device 1 may be stretched in the y direction and the -y direction. In another embodiment, the display device 1 may be stretched in the y direction or the -y direction while one side of the display device 1 is fixed.

The display device 1 may be stretched in a plurality of directions, e.g., the first direction (e.g., the x direction and/or the -x direction) and the second direction (e.g., the y direction and/or the -y direction) by an external force applied by an external object or a part of a user’s body. As illustrated in FIG. 2D, the display area DA and/or the non-display area NDA of the display device 1 may be stretched in the ±x direction and the ±y direction.

The display device 1 may be stretched in the third direction (e.g., the z direction or the -z direction) by an external force applied by an external object or a part of a user’s body. In an embodiment, FIG. 2E illustrates that a portion of the display device 1, e.g., a portion of the display area DA protrudes in the z direction. In another embodiment, a portion of the display device 1, e.g., a portion of the display area DA may protrude in the -z direction (or may be recessed in the z direction).

The display device 1 may be stretched in a plurality of directions, e.g., the first direction (e.g., the x direction and/or the -x direction), the second direction (e.g., the y direction and/or the -y direction), and the third direction (e.g., the z direction and/or the -z direction), by an external force applied by an external object or a part of a user’s body. As illustrated in FIG. 2F, the display area DA and/or the non-display area NDA of the display device 1 may be stretched in the ±x direction, the ±y direction, and the ±z direction.

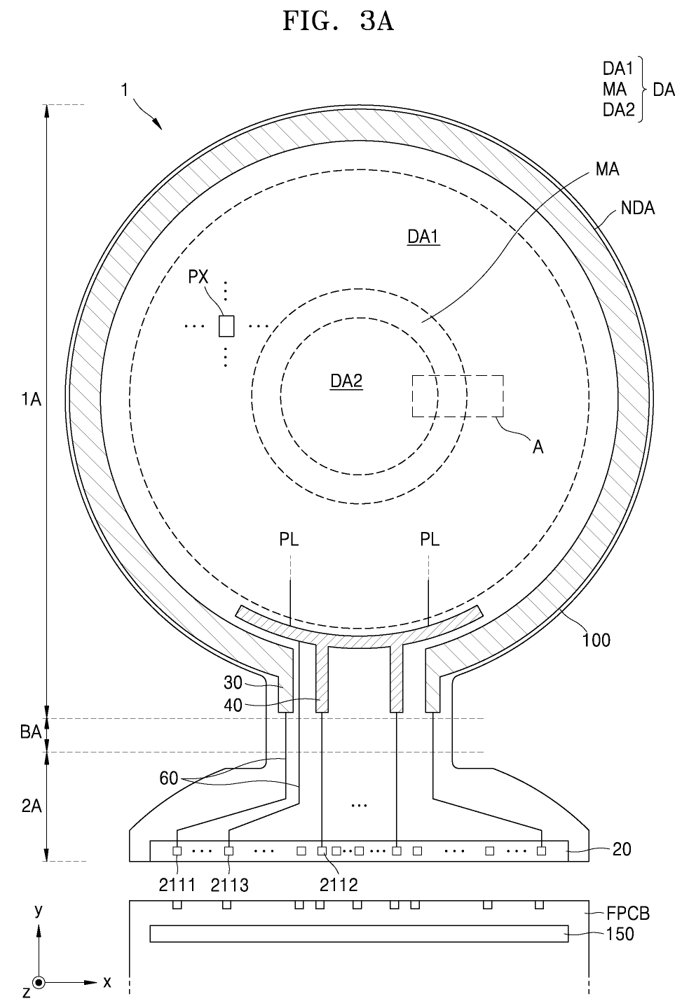

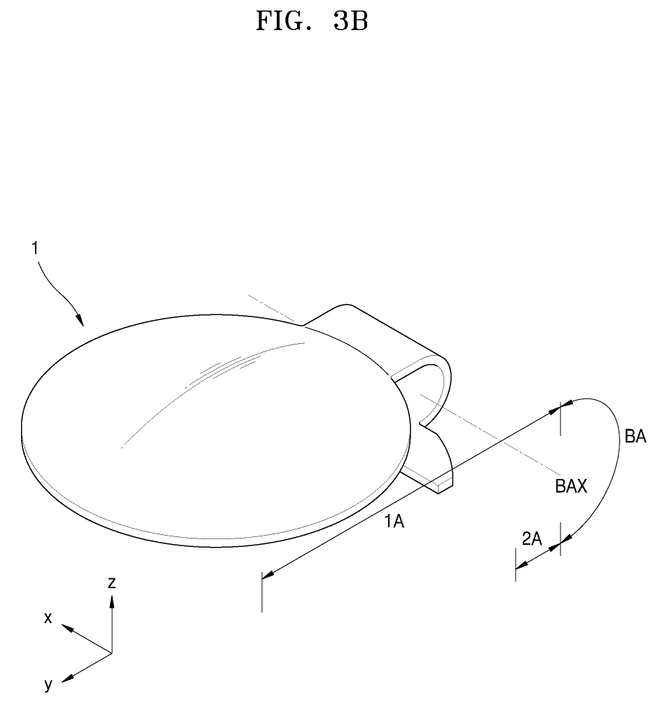

FIG. 3A is a plan view schematically illustrating an embodiment of a display device 1 according to the disclosure. FIG. 3B is a perspective view schematically illustrating an embodiment of the display device 1 according to the disclosure.

Referring to FIGS. 3A and 3B, the display device 1 may include a substrate 100. The substrate 100 may have a display area DA and a non-display area NDA that is a non-display area outside the display area DA. At this time, the substrate 100 may include a first area 1A, a second area 2A, and a bending area BA. In this case, the first area 1A may be a display unit, and the second area 2A may be a connection portion connected to an external device. At this time, the display unit may have a display area DA exposed to the outside and may implement an image according to the operation of the display area DA. The display area DA as described above may be included in the first area 1A, and the non-display area NDA may include a portion of the first area 1A excluding the display area DA, the second area 2A, and the bending area BA.

The first area 1A may have a non-rectangular shape. The non-rectangular shape may be, e.g., a circular shape, an elliptical shapes, a polygonal shape, a portion of which is circular, or a polygonal shape other than a rectangular shape. Of course, the first area 1A may have a rectangular shape or a rectangular shape with round corners.

As illustrated in FIG. 3B, the display device 1 may have a dome shape in the first area 1A. In an embodiment, the display device 1 may be stretched in the first direction (e.g., the x direction and/or the -x direction), the second direction (e.g., the y direction and/or the -y direction), and the third direction (e.g., the z direction and/or the -z direction) in the first area 1A, as described with reference to FIG. 2F, for example. Therefore, each of the display area DA and the non-display area NDA disposed in the first area 1A may be stretched in the first direction (e.g., the x direction and/or the -x direction), the second direction (e.g., the y direction and/or the -y direction), and the third direction (e.g., the z direction and/or the -z direction).

The substrate 100 has the bending area BA extended in the first direction (e.g., the x direction and/or the -x direction). The bending area BA is disposed between the first area 1A and the second area 2A in the second direction (e.g., the y direction and/or the -y direction) crossing the first direction. In an embodiment, the substrate 100 may be bent about a bending axis BAX extending in the first direction (e.g., the x direction and/or the -x direction), as illustrated in FIG. 3B, for example. In FIG. 3B, the substrate 100 is illustrated as being bent with the same radius of curvature with respect to the bending axis BAX, but the disclosure is not limited thereto. The substrate 100 may be bent about the bending axis BAX with a non-uniform radius of curvature.

The substrate 100 may include various materials having flexible or bendable properties and may include polymer resin, such as polyethersulfone, polyacrylate, polyetherimide, polyethylene naphthalate, polyethylene terephthalate, polyphenylene sulfide, polyimide, polycarbonate, or cellulose acetate propionate, for example. The substrate 100 may have a single-layer or multilayer structure of the materials described above, and in the case of the multilayer structure, the substrate 100 may further include an inorganic layer.

The first area 1A includes the display area DA. Of course, the first area 1A includes, in addition to the display area DA, a portion of the non-display area NDA outside the display area DA, as illustrated in FIG. 3A. The second area 2A may include another portion of the non-display area NDA.

The display area DA may have a shape corresponding to the shape of a portion of the substrate 100. In FIG. 3A, an embodiment in which a portion of the substrate 100 has a circular shape and the display area DA has a circular shape corresponding to the shape of a portion of the substrate 100 is illustrated.

A plurality of pixels PX are included in the display area DA to implement an image. The plurality of pixels PX may be implemented by light-emitting elements, and the light-emitting elements may be driven by a pixel driving circuit connected thereto. The pixel driving circuit may include elements, such as a thin film transistor (“TFT”) and a storage capacitor. The pixel driving circuit may be connected to a scan line and a data line crossing the scan line. In addition, the pixel driving circuit may be connected to a driving voltage line PL.

Each of the pixels PX may emit, e.g., red light, green light, blue light, or white light. The display area DA may provide a predetermined image through light emitted from the pixels PX. The pixel PX in the specification indicates a sub-pixel that emits light of any one color among red, green, blue, or white, as described above.

The non-display area NDA of the first area 1A is an area where the pixels PX are not disposed, and does not provide an image. A first power supply line 30 and a second power supply line 40, which apply different power voltages, may be disposed in the non-display area NDA.

The first power supply line 30 may be disposed to surround at least a portion of the display area DA in the non-display area NDA. The first power supply line 30 may be disposed to surround

most of the display area DA, except for a portion of the non-display area NDA where the second power supply line 40 is disposed. In some embodiments, the first power supply line 30 may be disposed to surround a portion of the second power supply line 40. The first power supply line 30 may be electrically connected to opposite electrodes of the light-emitting elements disposed in the display area DA and may transmit a common voltage. The first power supply line 30 may be connected to a pad 2111 of a pad portion 20. Since the first power supply line 30 is connected to the pad 2111, the first power supply line 30 may include a portion extending to the pad portion 20, e.g., a portion extending in the -y direction.

The second power supply line 40 may be disposed to correspond to a lower end portion of the display area DA in the non-display area NDA. A plurality of driving voltage lines PL that transmit driving voltages to a plurality of pixel driving circuits disposed in the display area DA may be connected to the second power supply line 40. The second power supply line 40 may be connected to a pad 2112 of the pad portion 20. Since the second power supply line 40 is connected to the pad portion 20, the second power supply line 40 may include a portion extending to the pad portion 20, e.g., a portion extending in the -y direction.

The pad portion 20 may be disposed in the second area 2A. The pad portion 20 includes a plurality of pads 2111, 2112, and 2113. The pad portion 20 may be exposed without being covered with an insulating layer and may be electrically connected to a control unit, such as a flexible printed circuit board FPCB or a driving driver 150.

The driving driver 150 may be disposed on a separate flexible printed circuit board FPCB, and the flexible printed circuit board FPCB may be connected to the pad portion 20. In another embodiment, the driving driver 150 may be disposed in various ways. In an embodiment, the driving driver 150 may be disposed directly on an upper portion of the substrate extending and protruding from the substrate 100 in a Chip On Glass (“COG”) or Chip On Plastic (“COP”) method, for example.

The control unit changes a plurality of image signals transmitted from the outside into a plurality of image data signals and transmits the changed signals to the display area DA through the pad portion 20. In addition, the control unit may receive a vertical synchronization signal, a horizontal synchronization signal, and a clock signal, generate a control signal for controlling driving of a gate driving circuit (not shown), and transmit the control signal to a gate driving circuit through the pad portion 20. The control unit may transmit different voltages respectively to the first power supply line 30 and the second power supply line 40 through the pad portion 20. The pad portion 20 may be connected to a plurality of fan-out wirings 60 and may transmit voltages and various signals to the display area DA.

The plurality of fan-out wirings 60 may be disposed to overlap the bending area BA. The fan-out wirings 60 may be disposed to extend from the first area 1A through the bending area BA to the second area 2A. The fan-out wirings 60 may extend across the bending axis BAX. The fan-out wirings 60 may be disposed in various ways, such as crossing perpendicularly to the bending axis BAX or crossing obliquely at a predetermined angle. In addition, the fan-out wirings 60 may have various shapes, such as a curved shape or a zigzag shape, rather than a straight-line shape.

The display area DA may include a first display area DA1 and a second display area DA2. The second display area DA2 may be surrounded by the first display area DA1. The second display area DA2 may be disposed in an area of the display area DA that receives less stress due to stretching. The modulus of the second display area DA2 may be provided to be greater than the modulus of the first display area DA1. The modulus of the second display area DA2 may be provided to be 100 times to 500 times greater than the modulus of the first display area DA1. In an embodiment, the modulus of the second display area DA2 may be 5 gigapascals (GPa) to 10 GPa, and the modulus of the first display area DA1 may be 20 megapascals (MPa) to 50 MPa, for example.

The elongation of the second display area DA2 may be provided to be less than the elongation of the first display area DA1. In the specification, the elongation is a numerical value representing a change in length (ΔL/L) by which the display device 1 may be stretched without physical damage to the display device 1 when an external force is applied to the display device 1. Here, ΔL represents a change in length of the display device and L represents the initial length of the display device.

When the display device is stretched due to the difference between the modulus of the second display area DA2 and the modulus of the first display area DA1, the stretching may occur less in the second display area DA2 and occur more in the first display area DA1.

In the illustrated embodiment, a gate driving circuit that provides a scan signal and/or an emission control signal to the pixel driving circuits may be disposed in the second display area DA2. In some embodiments, the second display area DA2 may be disposed in the central portion of the display area DA. In a plan view, the gate driving circuit may be disposed in the central portion of the display device 1. The gate driving circuit may include a plurality of thin film transistors disposed therein and may provide various scan signals and/or emission control signals. Accordingly, the number of wirings connected to the gate driving circuit may be significant.

Since the gate driving circuit is disposed in the second display area DA2 that receives less stress due to stretching, the stress transmitted to the gate driving circuit when the display device 1 is stretched may be minimized and defects in the wirings connected to the gate driving circuit may be minimized.

The display area DA may further include a middle area MA disposed between the first display area DA1 and the second display area DA2. The middle area MA is an area that connects the first display area DA1 to the second display area DA2, and the modulus of the middle area MA may have a value between the modulus of the first display area DA1 and the modulus of the second display area DA2. The modulus control may be implemented by the shape of the substrate 100. The pixels PX may also be disposed in the middle area MA and the second display area DA2 and may implement an image.

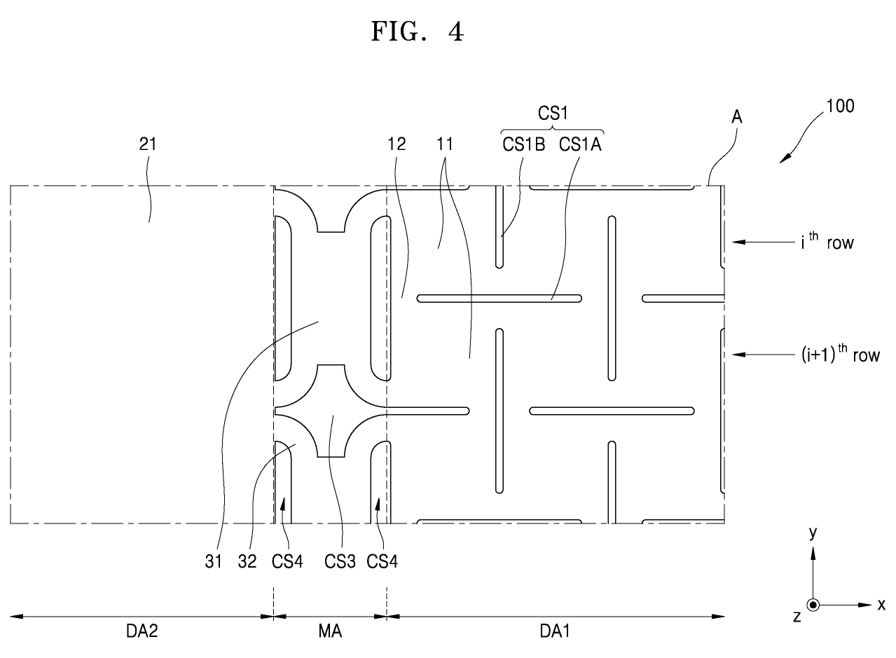

FIG. 4 is an enlarged plan view of an embodiment of region A of FIG. 3A as a portion of the display device according to the disclosure.

Referring to FIG. 4, the substrate 100 of the display device 1 may include first island portions 11 apart from each other in the first display area DA1, and first bridge portions 12 spaced apart from each other by first opening areas CS1 and connecting the neighboring (adjacent) first island portions 11 to each other. The width of the first bridge portion 12 may be provided to be less than the width of the first island portion 11.

The first opening area CS1 may have a bar shape. The first opening area CS1 may include a first sub-opening area CS1A extending in the first direction (e.g., the x direction or the -x direction) and a second sub-opening area CS1B extending in the second direction (e.g., the y direction or the -y direction). The first sub-opening area CS1A and the second sub-opening area CS1B may each have a bar shape. The first sub-opening area CS1A and the second sub-opening area CS1B may have substantially the same width and length. The length of each of the first sub-opening area CS1A and the second sub-opening area CS1B represents a value measured along the extension direction, and the width represents a value measured along a direction perpendicular to the longitudinal direction (e.g., the extension direction).

The shape of the second display area DA2 may be provided to be different from the shape of the first display area DA1. In an embodiment, the entirety of the second display area DA2 may be provided as one second island portion 21, for example. In the second display area DA2, the substrate 100 may be disposed continuously. Since the second display area DA2 does not define an opening area, the modulus of the second display area DA2 may be provided to be greater than the modulus of the first display area DA1. In another embodiment, the second display area DA2 may be provided with a plurality of second island portions and a plurality of second opening areas disposed therebetween, and the number and size of the plurality of second opening areas may be provided to be less than the number and size of the first opening areas CS1.

The middle area MA may include third island portions 31 apart from each other and third bridge portions 32. The neighboring (adjacent) third island portions 31 may be disposed spaced apart from each other by third opening areas CS3. The third island portions 31 and the first island portions 11, or the third island portions 31 and the second island portions 21 may be disposed spaced apart from each other by fourth opening areas CS4. The fourth opening areas CS4 may be provided in a bar shape between the first display area DA1 and the middle area MA or between the second display area DA2 and the middle area MA.

The shape of the third opening area CS3 may be provided to be different from the shape of the first opening area CS1. The shape of the third opening area CS3 may be provided in a shape similar to a rhombus. The size of the third opening area CS3 may be provided to be different from the size of the first opening area CS1. The shape of the third opening area CS3 may be provided to be different from the shape of the fourth opening area CS4. The fourth opening area CS4 may be provided in a bar shape extending in the y direction.

Any one row of the third island portions 31 disposed in the middle area MA may correspond to a plurality of rows of the first island portions 11 disposed in the first display area DA1. In an embodiment, any one row of the third island portions 31 disposed in the middle area MA may be disposed to correspond to first island portions 11 disposed in an i^{th} row and first island portions 11 disposed in an (i+1)^{th} row in the display area DA (where i is a positive number greater than 0), for example. In another embodiment, any one row of the third island portions 31 may correspond to n rows of the first island portions 11 (where n is a positive number greater than or equal to 3).

The third bridge portions 32 may connect the third island portions 31 to the first island portions 11, or may connect the third island portions 31 to the second island portions 21. In an embodiment, one end of the third bridge portion 32 may be connected to the edge of one side of the third island portion 31, and an opposite end of the third bridge portion 32 may be connected to the edge of one side of the first island portion 11, for example. In an alternative embodiment, one end of the third bridge portion 32 may be connected to the edge of one side of the third island portion 31, and an opposite end of the third bridge portion 32 may be connected to one side of the second island portion 21.

The third bridge portion 32 may have a curved shape. In an embodiment, the third bridge portion 32 may be provided in a shape of an arc that is a portion of a circle. In another embodiment, the third bridge portion 32 may be provided in a C shape or an S shape, for example. The width of the third bridge portion 32 may be provided to be less than the width of the third island portion 31.

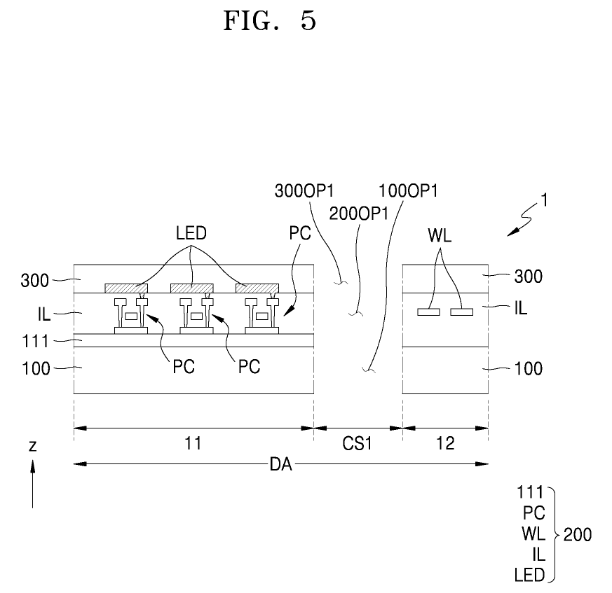

FIG. 5 is a cross-sectional view schematically illustrating an embodiment of the first island portion 11 and the first bridge portion 12, which are disposed in the display area DA of the display device 1, according to the disclosure.

Referring to FIG. 5, the first island portion 11 and the first bridge portion 12 disposed in the display area DA may be spaced apart from each other with the first opening area CS1 therebetween. The first island portion 11 may include light-emitting elements LED and a circuit for driving the light-emitting elements electrically connected thereto, such as pixel driving circuits PC, and the first bridge portion 12 may include wirings WL electrically connected to the pixel driving circuits PC respectively disposed in the neighboring (adjacent) first island portions 11.

When examining the first island portion 11, a buffer layer 111 including an inorganic insulating material may be disposed on a substrate 100, and the pixel driving circuits PC may be disposed on the buffer layer 111. An insulating layer IL including an inorganic insulating material and/or an organic insulating material may be disposed between the pixel driving circuits PC and the light-emitting elements LED. The light-emitting element LED may be disposed on the insulating layer IL and may be electrically connected to the corresponding pixel driving circuit PC. The light-emitting elements LED may emit pieces of light of different colors or the same color. In an embodiment, the light-emitting elements LED may each emit red light, green light, and blue light. In some embodiments, the light-emitting elements LED may emit white light. In another

embodiment, the light-emitting elements LED may each emit red light, green light, blue light, and white light.

The substrate 100 may include polymer resin, such as polyethersulfone, polyarylate, polyether imide, polyethylene naphthalate, polyethylene terephthalate, polyphenylene sulfide, polyimide, polycarbonate, cellulose triacetate, or cellulose acetate propionate. In an embodiment, the substrate 100 may be a single layer including the polymer resin described above. In another embodiment, the substrate 100 may have a multilayer structure including a base layer including the polymer resin described above and a barrier layer including an inorganic insulating material. The substrate 100 including the polymer resin may be flexible, rollable, or bendable.

In an embodiment, although FIG. 5 illustrates that three pixel driving circuits PC are disposed in each of the first island portions 11 and three light-emitting elements LED are respectively connected to the three pixel driving circuits PC, the disclosure is not limited thereto. In another embodiment, the number of pixel driving circuits PC and light-emitting elements LED disposed in the first island portion 11 may be one, two, or four or more.

An encapsulation layer 300 may be disposed on the light-emitting elements LED and may protect the light-emitting elements LED from an external force and/or moisture penetration. The encapsulation layer 300 may include an inorganic encapsulation layer and/or an organic encapsulation layer. In some embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material, such as resin. In some embodiments, the encapsulation layer 300 may include urethane epoxy acrylate. The encapsulation layer 300 may include a photosensitive material, such as a photoresist.

When examining the first bridge portion 12, an insulating layer IL including an organic insulating material may be disposed on the substrate 100. When the display device 1 is stretched, the first bridge portion 12, which is deformed relatively greatly, may not have a layer including an inorganic insulating material that is prone to cracks, unlike the first island portion 11.

In an embodiment, the substrate 100 corresponding to the first bridge portion 12 may have the same stack structure as the substrate 100 corresponding to the first island portion 11. In an embodiment, the substrate 100 corresponding to the first bridge portion 12 and the substrate 100

corresponding to the first island portion 11 may be polymer resin layers formed together in the same process. In another embodiment, the substrate 100 corresponding to the first bridge portion 12 may have a different stack structure from the substrate 100 corresponding to the first island portion 11. In some embodiments, the substrate 100 corresponding to the first bridge portion 12 may have a multilayer structure including a base layer including polymer resin and a barrier layer including an inorganic insulating material, and the substrate 100 corresponding to the first bridge portion 12 may have a structure of a polymer resin layer without a layer including an inorganic insulating material.

As described above, the wirings WL of the first bridge portion 12 may include a signal line (e.g., a gate line, a data line, etc.) for providing an electrical signal to the transistor included in the pixel driving circuit PC of the first island portion 11, or may include a voltage line (e.g., a driving voltage line, an initialization voltage line, etc.) for providing a voltage to the transistor included in the pixel driving circuit PC of the first island portion 11. The encapsulation layer 300 may also be disposed on the first bridge portion 12. In another embodiment, the encapsulation layer 300 may not be in the first bridge portion 12.

Referring to FIGS. 4 and 5, the substrate 100 corresponding to the first island portion 11 and the substrate 100 corresponding to the first bridge portion 12 may be connected to each other. In other words, the plan view illustrated in FIG. 4 may be substantially the same as the plan view of the substrate 100 in FIG. 5. In other words, the substrate 100 may include an area corresponding to the first island portion 11, an area corresponding to the first bridge portion 12, and an opening 100OP1 having the same shape as that of the first opening area CS1.

Similarly, the encapsulation layer 300 corresponding to the first island portion 11 and the encapsulation layer 300 corresponding to the first bridge portion 12 may be connected to each other. In an embodiment, the plan view illustrated in FIG. 4 may be substantially the same as the plan view of the encapsulation layer 300, for example. In other words, the encapsulation layer 300 may include an area corresponding to the first island portion 11, an area corresponding to the first bridge portion 12, and an opening 300OP1 having the same shape as that of the first opening area CS1.

A circuit light-emitting element layer 200 between the substrate 100 and the encapsulation layer 300 may include a buffer layer 111, a pixel driving circuit PC, a wiring WL, an insulating layer IL, and a light-emitting element LED. Similar to the substrate 100, the plan view illustrated

in FIG. 4 may be substantially the same as the plan view of the circuit light-emitting element layer 200. In other words, the circuit light-emitting element layer 200 may define an opening 200OP1 having the same shape as that of the first opening area CS1.

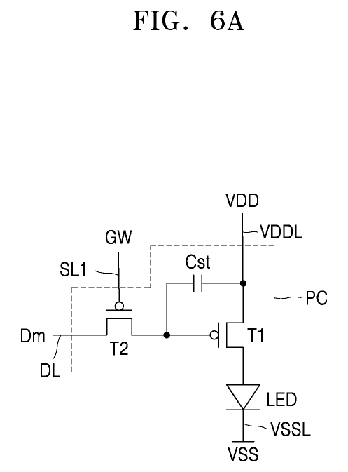

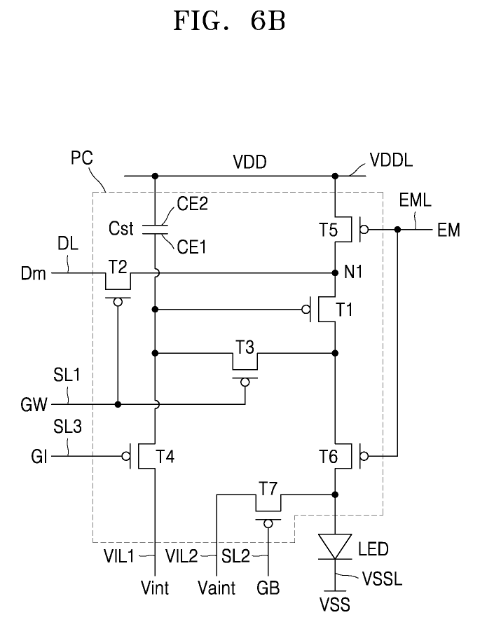

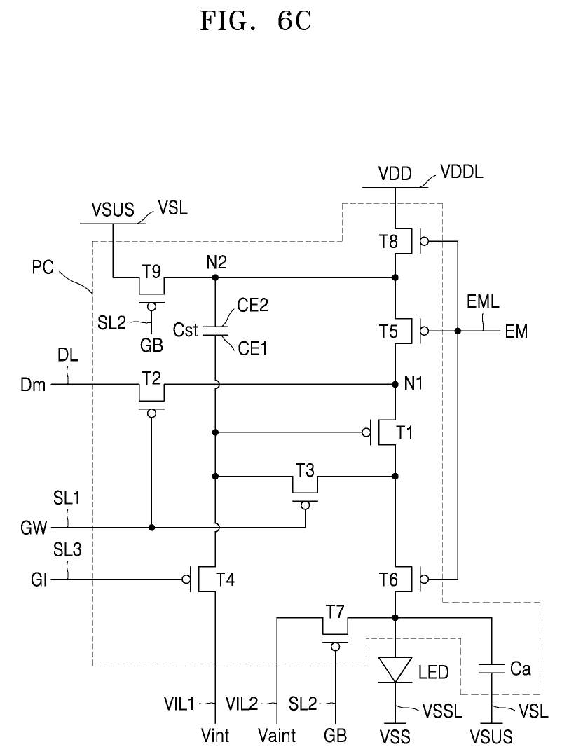

FIGS. 6A to 6C are equivalent circuit diagrams of an embodiment of a sub-pixel of a display device 1, according to the disclosure.

Referring to FIG. 6A, a light-emitting element LED corresponding to the sub-pixel may be electrically connected to a pixel driving circuit PC, and the pixel driving circuit PC may include a first transistor T1, a second transistor T2, and a storage capacitor Cst. The pixel driving circuit PC may be electrically connected to signal lines and voltage lines. The signal lines may include a gate line, such as a first scan line SL1, and a data line DL, and the voltage lines may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may transmit, to the first transistor T1, a data signal Dm input from the data line DL, in response to the first scan signal GW input from the first scan line SL1.

The storage capacitor Cst may be electrically connected to the second transistor T2 and the first voltage line VDDL and may store a voltage corresponding to the difference between a voltage received from the second transistor T2 and a first power supply voltage VDD supplied through the first voltage line VDDL.

The first transistor T1 is a driving transistor and may control a driving current flowing through the light-emitting element LED. The first transistor T1 may be connected to the first voltage line VDDL and the storage capacitor Cst. The first transistor T1 may control the driving current flowing from the first voltage line VDDL to the light-emitting element LED according to a voltage value stored in the storage capacitor Cst. The light-emitting element LED may emit light having a predetermined luminance according to the driving current. A first electrode of the light-emitting element LED may be electrically connected to the first transistor T1, and a second electrode may be electrically connected to the second voltage line VSSL that supplies a second power supply voltage VSS.

FIG. 6A illustrates that the pixel driving circuit PC includes two transistors and one storage capacitor, but in another embodiment, the pixel driving circuit PC may include three or more transistors.

Referring to FIG. 6B, the pixel driving circuit PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit PC may be electrically connected to signal lines and voltage lines. The signal lines may include a data line DL and gate lines, such as a first scan line SL1, a second scan line SL2, a third scan line SL3, and an emission control line EML. The voltage lines may include first and second initialization voltage lines VIL1 and VIL2 and a first voltage line VDDL.

The first voltage line VDDL may transmit a first power supply voltage VDD to the first transistor T1. The first initialization voltage line VIL1 may transmit, to the pixel driving circuit PC, a first initialization voltage Vint for initializing the first transistor T1. The second initialization voltage line VIL2 may transmit, to the pixel driving circuit PC, a second initialization voltage Vaint for initializing a first electrode of a light-emitting element LED.

The first transistor T1 may be electrically connected to the first voltage line VDDL via the fifth transistor T5 and may be electrically connected to the light-emitting element LED via the sixth transistor T6. The first transistor T1 acts as a driving transistor, receives a data signal Dm according to the switching operation of the second transistor T2, and supplies a driving current to the light-emitting element LED.

The second transistor T2 is a data write transistor and may be electrically connected to the first scan line SL1 and the data line DL. The second transistor T2 is electrically connected to the first voltage line VDDL via the fifth transistor T5. The second transistor T2 is turned on in response to a first scan signal GW received through the first scan line SL1 and performs a switching operation to transmit the data signal Dm received through the data line DL to a first node N1.

The third transistor T3 is electrically connected to the first scan line SL1 and electrically connected to the light-emitting element LED via the sixth transistor T6. The third transistor T3 may be turned on in response to the first scan signal GW received through the first scan line SL1 and diode-connect the first transistor T1.

The fourth transistor T4 is a first initialization transistor and is electrically connected to the third scan line SL3 and the first initialization voltage line VIL1. The fourth transistor T4 is turned on in response to a third scan signal GI received through the third scan line SL3 and initializes the voltage of the gate electrode of the first transistor T1 by transmitting the first initialization voltage Vint from the first initialization voltage line VIL1 to the gate electrode of the first transistor T1. The third scan signal GI may correspond to the first scan signal of another pixel driving circuit disposed in a previous row of the corresponding pixel driving circuit PC.

The fifth transistor T5 may be an operation control transistor and the sixth transistor T6 may be an emission control transistor. The fifth transistor T5 and the sixth transistor T6 are electrically connected to the emission control line EML, are simultaneously turned on in response to an emission control signal EM received through the emission control line EML, and form a current path through which the driving current flows in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 may be turned on in response to a second scan signal GB received through the second scan line SL2 and may initialize the first electrode of the light-emitting element LED by transmitting the second initialization voltage Vaint from the second initialization voltage line VIL2 to the first electrode of the light-emitting element LED.

The storage capacitor Cst may include a first electrode CE1 and a second electrode CE2. The first electrode CE1 is electrically connected to the gate electrode of the first transistor T1 and the second electrode CE2 is electrically connected to the first voltage line VDDL. The storage capacitor Cst may store and maintain a voltage corresponding to the voltage difference between the first voltage line VDDL and the gate electrode of the first transistor T1, and thus, the voltage applied to the gate electrode of the first transistor T1 may be maintained.

Referring to FIG. 6C, a pixel driving circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit PC is electrically connected to signal lines and voltage lines. The signal lines may include a data line DL and gate lines, such as a first scan line SL1, a second scan line SL2, a third scan line SL3, and an emission control line EML. The voltage lines may include first and second initialization voltage lines VIL1 and VIL2, a sustain voltage line VSL, and a first voltage line VDDL.

The first voltage line VDDL may transmit a first power supply voltage VDD to the first transistor T1. The first initialization voltage line VIL1 may transmit, to the pixel driving circuit PC, a first initialization voltage Vint for initializing the first transistor T1. The second initialization voltage line VIL2 may transmit, to the pixel driving circuit PC, a second initialization voltage Vaint for initializing a first electrode of a light-emitting element LED. The sustain voltage line VSL may provide a sustain voltage VSUS to a second node N2, e.g., a second electrode CE2 of the storage capacitor Cst, in an initialization period and a data write period.

The first transistor T1 may be electrically connected to the first voltage line VDDL via the fifth transistor T5 and the eighth transistor T8 and may be electrically connected to the light-emitting element LED via the sixth transistor T6. The first transistor T1 acts as a driving transistor and may receive a data signal Dm according to the switching operation of the second transistor T2 and supply a driving current to the light-emitting element LED.

The second transistor T2 is electrically connected to the first scan line SL1 and the data line DL and electrically connected to the first voltage line VDDL via the fifth transistor T5 and the eighth transistor T8. The second transistor T2 is turned on in response to a first scan signal GW received through the first scan line SL1 and performs a switching operation to transmit, to a first node N1, the data signal Dm transmitted through the data line DL.

The third transistor T3 is electrically connected to the first scan line SL1 and electrically connected to the light-emitting element LED via the sixth transistor T6. The third transistor T3 may be turned on in response to the first scan signal GW received through the first scan line SL1 and may compensate for a threshold voltage of the first transistor T1 by diode-connecting the first transistor T1.

The fourth transistor T4 is electrically connected to the third scan line SL3 and the first initialization voltage line VIL1, is turned on in response to a third scan signal GI received through the third scan line SL3, and initializes the voltage of the gate electrode of the first transistor T1 by transmitting the first initialization voltage Vint from the first initialization voltage line VIL1 to the gate electrode of the first transistor T1. The third scan signal GI may correspond to the first scan signal of another pixel driving circuit disposed in the previous row of the corresponding pixel driving circuit PC.

The fifth transistor T5, the sixth transistor T6, and the eighth transistor T8 are electrically connected to the emission control line EML, are simultaneously turned on in response to an emission control signal EM received through the emission control line EML, and form a current path through which the driving current flows in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on in response to a second scan signal GB received through the second scan line SL2 and initializes the first electrode of the light-emitting element LED by transmitting the second initialization voltage Vaint from the second initialization voltage line VIL2 to the first electrode of the light-emitting element LED.

The ninth transistor T9 may be electrically connected to the second scan line SL2, the second electrode CE2 of the storage capacitor Cst, and the sustain voltage line VSL. The ninth transistor T9 may be turned on in response to the second scan signal GB received through the second scan line SL2 and may transmit the sustain voltage VSUS to the second node N2, e.g., the second electrode CE2 of the storage capacitor Cst, in the initialization period and the data write period.

Each of the eighth transistor T8 and the ninth transistor T9 may be electrically connected to the second node N2, e.g., the second electrode CE2 of the storage capacitor Cst. In some embodiments, in the initialization period and the data write period, the eighth transistor T8 may be turned off and the ninth transistor T9 may be turned on, and in the emission period, the eighth transistor T8 may be turned on and the ninth transistor T9 may be turned off. Since the sustain voltage VSUS is transmitted to the second node N2 in the initialization period and the data write period, the luminance uniformity (e.g., long range uniformity (“LRU”)) of the display device according to the voltage drop of the first voltage line VDDL may be improved.

The storage capacitor Cst includes a first electrode CE1 and a second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may store and maintain a voltage corresponding to the voltage difference between the first electrode of the light-emitting element LED and the sustain voltage line VSL while the seventh transistor T7 and the ninth transistor T9 are turned on, and thus, the problem that increases black luminance when the sixth transistor T6 is turned off may be prevented.

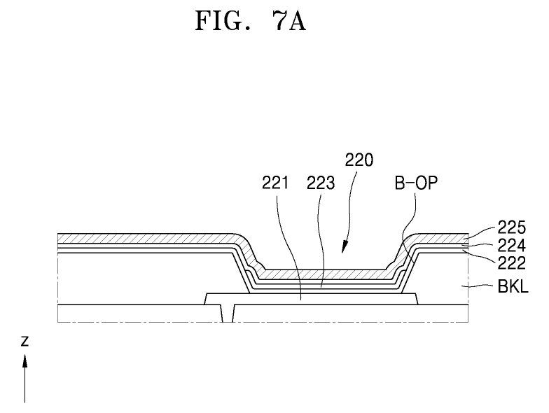

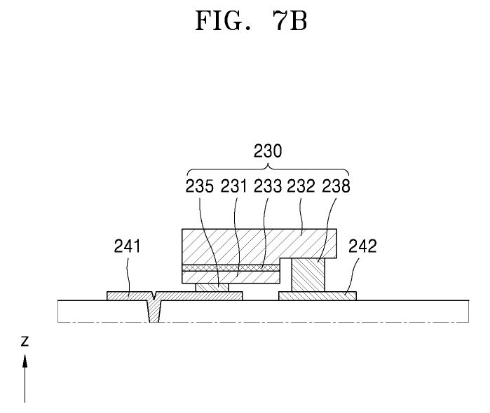

FIG. 7A is a cross-sectional view schematically illustrating an embodiment of a light-emitting element of a display device, according to the disclosure.

Referring to FIG. 7A, the light-emitting element in an embodiment of the disclosure may include an organic light-emitting diode 220 including an organic material. The organic light-emitting diode 220 may include a first electrode 221 disposed on an insulating layer, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

The edge of the first electrode 221 may be covered by a bank layer BKL including an insulating material. The bank layer BKL may define an opening B-OP overlapping the central portion of the first electrode 221.

The first electrode 221 may include a conductive oxide, such as indium tin oxide (“ITO”), indium zinc oxide IZO, zinc oxide (ZnO), indium oxide (In₂O₃), indium gallium oxide (“IGO”), or aluminum zinc oxide (“AZO”). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any combination thereof. In another embodiment, the first electrode 221 may further include a layer including ITO, IZO, ZnO, AZO, or In₂O₃ above and/or below the reflective layer described above.

The emission layer 223 may include a relatively high molecular weight organic material or a relatively low molecular weight organic material that emits light of a predetermined color. The first functional layer 222 may include a hole transport layer (“HTL”) and/or a hole injection layer (“HIL”). The second functional layer 224 may include an electron transport layer (“ETL”) and/or an electron injection layer (“EIL”).

The second electrode 225 may include a conductive material having a relatively low work function. In an embodiment, the second electrode 225 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium Ca, or any alloy thereof, for example. In an alternative embodiment, the second electrode 225 may further include a layer including ITO, IZO, ZnO, AZO, or In₂O₃ on the (semi)transparent layer including the material described above.

FIG. 7B is a cross-sectional view schematically illustrating an embodiment of a light-emitting element of a display device, according to the disclosure.

Referring to FIG. 7B, the light-emitting element in an embodiment of the disclosure may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242, which are disposed in the same layer.

In some embodiments, the first semiconductor layer 231 may include a p-type semiconductor layer. The p-type semiconductor layer may include or consist of semiconductor materials having a composition formula of InₓAl_{y}Ga_{1-x-y}N (0≤x≤1, 0≤y≤1, 0≤x+y≤1), e.g., GaN, AlN, AlGaN, InGaN, InN, InAlGaN, or AlInN, and may be doped with a p-type dopant, such as Mg, Zn, Ca, Sr, or Ba.

The second semiconductor layer 232 may include an n-type semiconductor layer, for example. The n-type semiconductor layer may include or consist of semiconductor materials having a composition formula of InₓAl_{y}Ga_{1-x-y}N (0≤x≤1, 0≤y≤1, 0≤x+y≤1), e.g., GaN, AlN, AlGaN, InGaN, InN, InAlGaN, or AlInN, and may be doped with an n-type dopant, such as Si, Ge, or Sn.

The intermediate layer 233 is an area in which electrons and holes recombine, and as the electrons and the holes recombine, the intermediate layer 233 may transition to a relatively low energy level to generate light having a wavelength corresponding thereto. In an embodiment, the intermediate layer 233 may include a semiconductor material having a composition formula of InₓAl_{y}Ga_{1-x-y}N (0≤x≤1, 0≤y≤1, 0≤x+y≤1), and may have a single quantum well structure or a multi quantum well (“MQW”) structure, for example. In addition, the intermediate layer 233 may have a quantum wire structure or a quantum dot structure.

Although FIG. 7B illustrates that the first semiconductor layer 231 includes a p-type semiconductor layer and the second semiconductor layer 232 includes an n-type semiconductor layer, the disclosure is not limited thereto. In another embodiment, the first semiconductor layer 231 may include an n-type semiconductor layer and the second semiconductor layer 232 may include a p-type semiconductor layer.

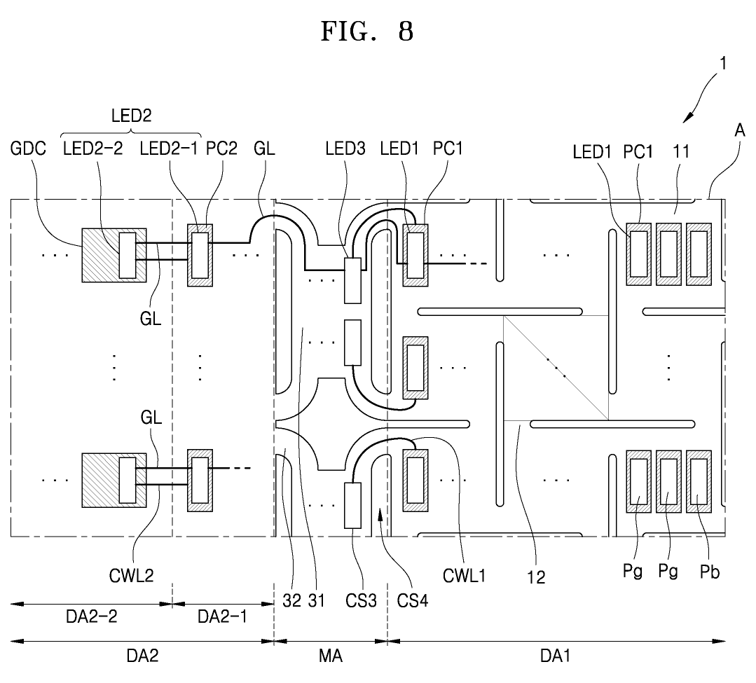

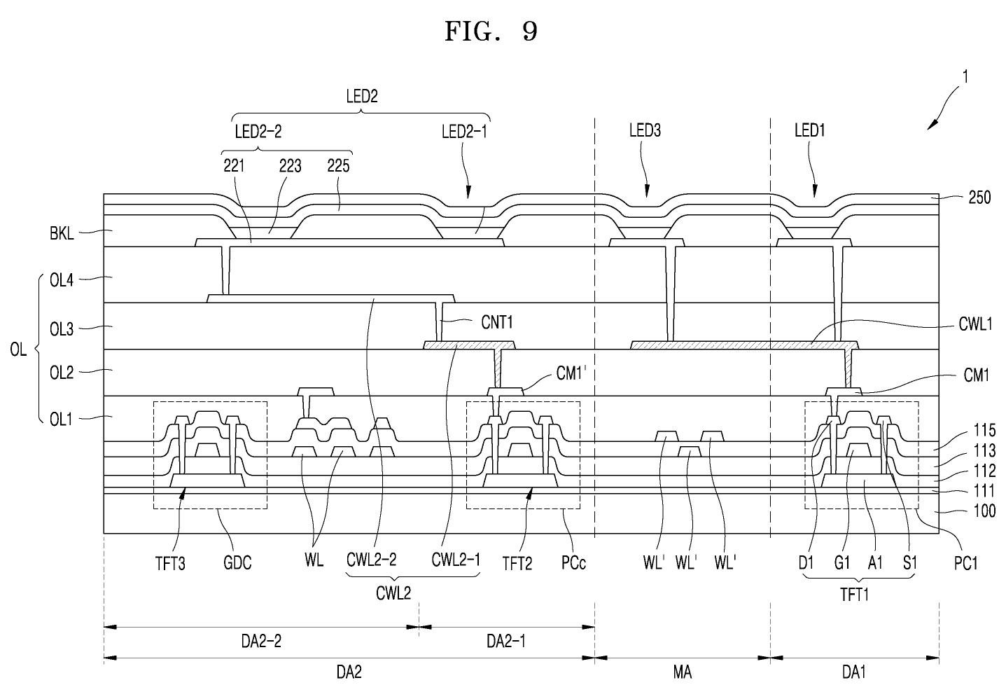

FIG. 8 is an enlarged plan view of an embodiment of region A of FIG. 3A as a portion of a display device according to the disclosure. Specifically, some pixel driving circuits, light-emitting elements, and gate driving circuits disposed in the display area DA are illustrated.

Referring to FIG. 8, a first light-emitting diode LED1 and a first pixel driving circuit PC1 that drives the first light-emitting diode LED1 may be disposed in a first display area DA1. The first light-emitting diode LED1 may overlap the first pixel driving circuit PC1. A plurality of first light-emitting diodes LED1 that emit different colors from each other and a plurality of first pixel driving circuits PC1 that drive the plurality of first light-emitting diodes LED1 may be disposed in each of first island portions 11 of the first display area DA1.

In an embodiment, three first pixel driving circuits PC1 and three first light-emitting diodes LED1 may be disposed in one first island portion 11, for example. The three first light-emitting diodes LED1 may act as a red pixel Pr, a green pixel Pg, and a blue pixel Pb, respectively. The red pixel Pr, the green pixel Pg, and the blue pixel Pb may be disposed in a stripe arrangement in a single row along the first direction, as illustrated in the drawing. However, the disclosure is not limited thereto. The arrangement of the pixels may be disposed in various ways, such as mosaic arrangement, diamond arrangement, and Pentile^{TM} arrangement.

A second light-emitting diode LED2 and a second pixel driving circuit PC2 that drives the second light-emitting diode LED2 may be disposed in a second display area DA2. In addition, a gate driving circuit GDC may be disposed in the second display area DA2. The gate driving circuit GDC is a circuit that provides scan signals and/or emission control signals to the first pixel driving circuits PC1 and the second pixel driving circuits PC2, and may be connected to a gate line GL. The gate line GL may transmit the scan signals or the emission control signals to the pixel driving circuits via a scan line or an emission control line.

The second light-emitting diode LED2 may include a second-1 light-emitting diode LED2-1 and a second-2 light-emitting diode LED2-2. The second-1 light-emitting diode LED2-1 and the second-2 light-emitting diode LED2-2 may be connected to one second pixel driving circuit PC2 and may be driven simultaneously. The second-1 light-emitting diode LED2-1 may be disposed to overlap the second pixel driving circuit PC2. The second-2 light-emitting diode LED2-2 may be disposed to overlap the gate driving circuit GDC. As the second-2 light-emitting diode LED2-2 is disposed to overlap the gate driving circuit GDC, an image may also be implemented in the second display area DA2 in which the gate driving circuit GDC is disposed.

The second display area DA2 may be divided into a second-1 display area DA2-1 in which the gate driving circuit GDC is disposed and a second-2 display area DA2-2 in which the second pixel driving circuit PC2 is disposed. The second-2 display area DA2-2 is an area disposed at the edge of the second display area DA2 and may be disposed between the second-1 display area DA2-1 and the middle area MA. The second pixel driving circuit PC2 may be disposed next (adjacent) to the first display area DA1 than the gate driving circuit GDC.

In the illustrated embodiment, since the gate driving circuit GDC is disposed in the second display area DA2 having a relatively large modulus, less stress due to deformation may be transmitted to the gate driving circuit GDC even when the display device is deformed.

When the gate driving circuit GDC is disposed outside the display area DA, an external force may be easily applied to the gate driving circuit GDC during the process of stretching the display device, and the external force may cause defects, such as cracks, in the gate driving circuit GDC. In this case, even when defects occur in a portion of the gate driving circuit GDC, defects occur throughout the entirety of the display device.

In the illustrated embodiment, the gate driving circuit GDC is disposed inside the display area DA to minimize an external force applied to the gate driving circuit GDC, thereby ensuring reliability of the entirety of the display device 1.

A third light-emitting diode LED3 may be disposed in the middle area MA. The third light-emitting diode LED3 may be driven by the first pixel driving circuit PC1 disposed in the first display area DA1. No pixel driving circuit may be disposed in the middle area MA. The first pixel driving circuit PC1 that simultaneously drives the third light-emitting diode LED3 and the first light-emitting diode LED1 may be disposed in an area disposed next (adjacent) to the middle area MA of the first display area DA1. The first light-emitting diode LED1 may overlap the first pixel

driving circuit PC1. The third light-emitting diode LED3 may be disposed in the third island portion 31 of the middle area MA and may overlap wirings passing through the middle area MA, e.g., the gate line GL. As the third light-emitting diode LED3 is disposed in the middle area MA, a boundary between the first display area DA1 and the second display area DA2 may be prevented from being visually recognized.

A wiring passing through the third bridge portion 32 of the middle area MA may be curved along the shape of the third bridge portion 32. Since the wiring has a curved shape, the wirings disposed in the third bridge portion 32 may receive less stress when the display device is stretched or compressed.

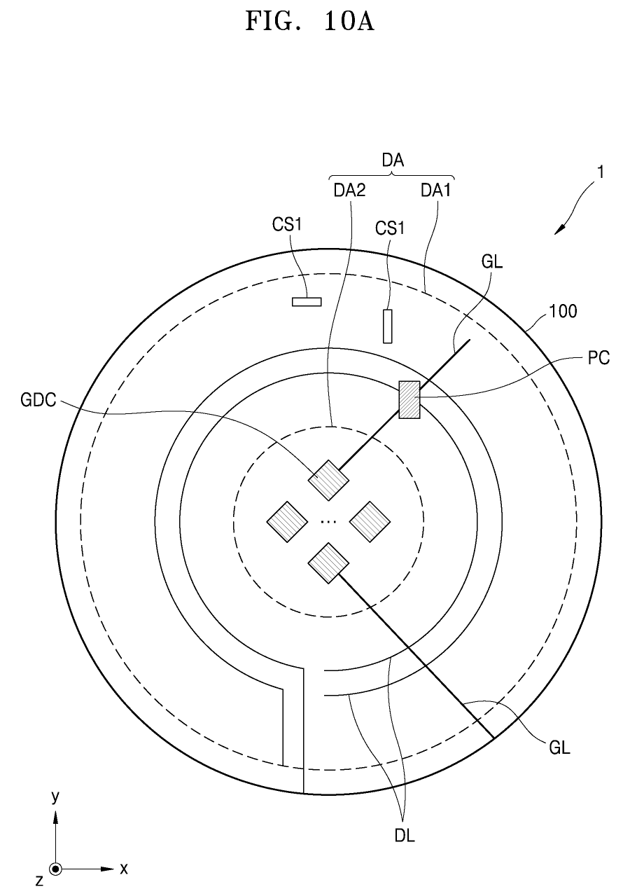

FIG. 9 is a cross-sectional view schematically illustrating an embodiment of a portion of a display device according to the disclosure. Specifically, FIG. 9 illustrates a portion of a first display area, a second display area, and a middle area of the display device.

Referring to FIG. 9, a first light-emitting diode LED1 and a first pixel driving circuit PC1 connected to the first light-emitting diode LED1 may be disposed in a first display area DA1. The first light-emitting diode LED1 may overlap the first pixel driving circuit PC1.

A second light-emitting diode LED2 may be disposed in the second display area DA2. The second light-emitting diode LED2 may include a second-1 light-emitting diode LED2-1 and a second-2 light-emitting diode LED2-2, which are connected to each other.

A second pixel driving circuit PC2 connected to the second light-emitting diode LED2 may be disposed in the second-1 display area DA2-1 of the second display area DA2. A gate driving circuit GDC that provides signals, such as scan signals and emission control signals, to pixel driving circuits PC1 and PC2 may be disposed in the second-2 display area DA2. The second-1 light-emitting diode LED2-1 may overlap the second pixel driving circuit PC2, and the second-2 light-emitting diode LED2-2 may overlap the gate driving circuit GDC.

A third light-emitting diode LED3 may be disposed in the middle area MA. The third light-emitting diode LED3 may be connected to the first pixel driving circuit PC1 disposed in the first display area DA1.

The first pixel driving circuit PC1 may include a first thin film transistor TFT1, the second pixel driving circuit PC2 may include a second thin film transistor TFT2, and the gate driving circuit GDC may include a third thin film transistor TFT3.

A first connection wiring CWL1 that connects the first pixel driving circuit PC1 to the third light-emitting diode LED3 may be disposed in the first display area DA1 and the middle area MA. A second connection wiring CWL2 that connects the second pixel driving circuit PC2 to the second-2 light-emitting diode LED2-2 may be disposed in the second-1 display area DA2-1 and the second-2 display area DA2-2. The second connection wiring CWL2 may include a second-1 connection wiring CWL2-1 and a second-2 connection wiring CWL2-2, which are disposed in different layers from each other.

The substrate 100 may include an insulating material, such as polymer resin, as described above. The substrate 100 may be a flexible substrate that is bendable, foldable, or rollable.

The buffer layer 111 may be disposed on the substrate 100, may reduce or prevent infiltration of foreign material, moisture, or ambient air from below the substrate 100, and may provide a flat surface on the substrate 100. The buffer layer 111 may include an inorganic material, such as an oxide or a nitride, an organic material, or an organic/inorganic composite material and may have a single-layer or multilayer structure including an inorganic material and an organic material. A barrier layer (not shown) that prevents infiltration of ambient air may be further included between the substrate 100 and the buffer layer 111. In some embodiments, the buffer layer 111 may include silicon oxide (SiO₂) or silicon nitride (SiNx).

A first thin film transistor TFT1, a second thin film transistor TFT2, and a third thin film transistor TFT3 may be disposed on the buffer layer 111. The first thin film transistor TFT1 may include a first semiconductor layer A1, a first gate electrode G1, a first source electrode S1, and a first drain electrode D1. The first thin film transistor TFT1 may be connected to the first light-emitting diode LED1 and the third light-emitting diode LED3 and may drive the first light-emitting diode LED1 and the third light-emitting diode LED3.

The second thin film transistor TFT2 may be connected to the second-1 light-emitting diode LED2-1 and the second-2 light-emitting diode LED2-2 and may drive the second-1 light-emitting diode LED2-1 and the second-2 light-emitting diode LED2-2. The third thin film transistor TFT3 is a thin film transistor included in the gate driving circuit GDC and may provide a driving signal, such as a scan signal.

Since the second thin film transistor TFT2 and the third thin film transistor TFT3 have a configuration that is similar to a configuration of the first thin film transistor TFT1, the description of the second thin film transistor TFT2 and the third thin film transistor TFT3 is replaced with the description of the first thin film transistor TFT1. The first thin film transistor TFT1 may include a first semiconductor layer A1, a first gate electrode G1, a first source electrode S1, and a first drain electrode D1.

The first semiconductor layer A1 may be disposed on the buffer layer 111 and may include polysilicon. In another embodiment, the first semiconductor layer A1 may include amorphous silicon. In another embodiment, the first semiconductor layer A1 may include an oxide of at least one selected from the group including or consisting of indium (In), gallium (Ga), stannum (Sn), zirconium (Zr), vanadium (V), hafnium (Hf), cadmium (“CD”), germanium (Ge), chromium (Cr), titanium (Ti), and zinc (Zn). The first semiconductor layer A1 may include a channel region, and a source region and a drain region doped with impurities.

A first gate insulating layer 112 may be disposed to cover the first semiconductor layer A1. The first gate insulating layer 112 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), or hafnium oxide (HfO₂). The first gate insulating layer 112 may be a single layer or layers including the inorganic insulating material described above.

The first gate electrode G1 may be disposed on the first gate insulating layer 112 to overlap the first semiconductor layer A1. The first gate electrode G1 may include molybdenum (Mo), aluminum (Al), copper (Cu), titanium (Ti), or the like and may include a single layer or layers. In an embodiment, the first gate electrode G1 may be a single Mo layer, for example.

The second gate insulating layer 113 may be disposed to cover the first gate electrode G1. The second gate insulating layer 113 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The second gate insulating layer 113 may be a single layer or layers including the inorganic insulating material described above.

Wirings WL and capacitor electrodes (not shown) may be disposed on the second gate insulating layer 113. Some of the wirings WL disposed in the second display area DA2 may be connected to the gate driving circuit GDC and transmit driving signals. The wirings WL may include aluminum (Al), platinum (Pt), palladium (Pd), silver (Ag), magnesium (Mg), gold (Au), nickel (Ni), neodymium (Nd), iridium (Ir), chromium (Cr), calcium Ca, molybdenum (Mo), titanium (Ti), tungsten (W), and/or copper (Cu) and may be a single layer or layers including the material described above.

An inter-insulating layer 115 may be formed on the second gate insulating layer 113 to cover the wirings WL. The inter-insulating layer 115 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), or hafnium oxide (HfO₂). The inter-insulating layer 115 may be a single layer or layers including the inorganic insulating material described above.

The first source electrode S1 and the first drain electrode D1 may be disposed on the inter-insulating layer 115. In addition, wirings WL' may be disposed on the inter-insulating layer 115. The wirings WL' and WL disposed in the middle area MA may overlap the third light-emitting diode LED3.

The first source electrode S1, the first drain electrode D1, and the wirings WL' may each include a conductive material including molybdenum (Mo), aluminum (Al), copper (Cu), titanium (Ti), or the like and may each be formed as a single layer or layers including the material described above. In an embodiment, the first source electrode S1 and the first drain electrode D1 may have a multilayer structure of Ti/Al/Ti, for example.

A first organic insulating layer OL1 may be disposed on the inter-insulating layer 115 to cover the first source electrode S1 and the first drain electrode D1. First connection electrodes CM1 and CM1' respectively connected to the pixel driving circuits PC1 and PC2 may be disposed on the first organic insulating layer OL1. The first connection electrodes CM1 and CM1' may each include a conductive material including molybdenum (Mo), aluminum (Al), copper (Cu), titanium (Ti), or the like and may be formed as a single layer or layers including the material described above.

A second organic insulating layer OL2 that covers the first connection electrodes CM1 and CM1' may be disposed on the first organic insulating layer OL1. A first connection wiring CWL1 and a second-1 connection wiring CWL2-1 may be disposed on the second organic insulating layer OL2. The first connection wiring CWL1 may be connected to the first connection electrode CM1 connected to the first pixel driving circuit PC1, and the second-1 connection wiring CWL2-1 may be connected to the first connection electrode CM1' connected to the second pixel driving circuit PC2.

The first connection wiring CWL1 and the second-1 connection wiring CWL2-1 may include a conductive material including molybdenum (Mo), aluminum (Al), copper (Cu), titanium (Ti), or the like and may be formed as a single layer or layers including the material described above. In an alternative embodiment, the first connection wiring CWL1 and the second-1 connection wiring CWL2-1 may include a conductive oxide, such as indium tin oxide (“ITO”), indium zinc oxide IZO, zinc oxide (ZnO), indium oxide (In₂O₃), indium gallium oxide (“IGO”), or aluminum zinc oxide (“AZO”).

A third organic insulating layer OL3 that covers the first connection wiring CWL1 and the second-1 connection wiring CWL2-1 may be disposed on the second organic insulating layer OL2. A second-2 connection wiring CWL2-2 may be disposed on the third organic insulating layer OL3. The second-2 connection wiring CWL2-2 may be connected to the second-1 connection wiring CWL2-1 through a contact hole CNT1 passing through the third organic insulating layer OL3.

The second-2 connection wiring CWL2-2 may include a conductive material including molybdenum (Mo), aluminum (Al), copper (Cu), titanium (Ti), conductive oxide, or the like and may be formed as a single layer or layers including the material described above.

The first connection wiring CWL1 may be disposed to extend from the first display area DA1 to the middle area MA. The first connection wiring CWL1 may extend through the third bridge portion (refer to 32 of FIG. 8) of the middle area MA to the third island portion (refer to 31 of FIG. 8).

The second-1 connection wiring CWL2-1 and the second-2 connection wiring CWL2-2 may be disposed to extend from the second-1 display area DA2-1 to the second-2 display area DA2-2. Accordingly, at least one of the second-1 connection wiring CWL2-1 and the second-2 connection wiring CWL2-2 may overlap the gate driving circuit GDC. Although the second connection wiring CWL2 is illustrated as including the second-1 connection wiring CWL2-1 and the second-2 connection wiring CWL2-2 disposed in different layers from each other, the disclosure is not limited thereto. The second connection wiring CWL2 may be variously modified, such as including only the second-1 connection wiring CWL2-1 or the second-2 connection wiring CWL2-2.

A fourth organic insulating layer OL4 may be disposed on the third organic insulating layer OL3 to cover the second-2 connection wiring CWL2-2. The fourth organic insulating layer OL4 may have a flat upper surface so that first electrodes 221 of the light-emitting diodes LED1, LED2, and LED3 disposed thereon may be flat.

The first organic insulating layer OL1, the second organic insulating layer OL2, the third organic insulating layer OL3, and the fourth organic insulating layer OL4 may include general-purpose polymer, such as benzocyclobutene (“BCB”), polyimide, hexamethyldisiloxane (“HMDSO”), polymethylmethacrylate (“PMMA”), or polystyrene, polymer derivatives having a phenolic group, acrylic-based polymer, imide-based polymer, aryl ether-based polymer, amide-based polymer, fluorine-based polymer, p-xylene-based polymer, or vinyl alcohol-based polymer. The first organic insulating layer OL1, the second organic insulating layer OL2, the third organic insulating layer OL3, and the fourth organic insulating layer OL4 may be variously modified, such as including the same material or different materials from each other.

The light-emitting diodes LED1, LED2, and LED3 may be disposed on the fourth organic insulating layer OL4. The light-emitting diodes LED1, LED2, and LED3 may include a first electrode 221, an emission layer 223, and a second electrode 225, as described with reference to FIG. 7A.

The first electrode 221 of the first light-emitting diode LED1 and the first electrode 221 of the third light-emitting diode LED2 may each be connected to the first connection wiring CWL1 through a contact hole. The first electrode 221 of the second-1 light-emitting diode LED2-1 and the first electrode 221 of the second-2 light-emitting diode LED2-2 may be integrally formed (or unitary). However, the disclosure is not limited thereto. The first electrode 221 of the second-1 light-emitting diode LED2-1 and the first electrode 221 of the second-2 light-emitting diode LED2-2 may be variously modified, such as each being connected to the second-2 connection wiring CWL2-2 through a contact hole.

A bank layer BKL may be disposed on the fourth organic insulating layer OL4 and may define emission areas of the light-emitting diodes LED1, LED2, and LED3. The bank layer BKL may cover the edges of the first electrodes 221 of the light-emitting diodes LED1, LED2, and LED3 and may define openings exposing the central portions of the first electrodes 221. The sizes and shapes of the emission areas of the light-emitting diodes LED1, LED2, and LED3 may be defined by the openings.

The bank layer BKL may include an organic insulating material, such as polyimide, polyamide, acrylic resin, benzocyclobutene, hexamethyldisiloxane (“HMDSO”), and phenol resin, and may be formed by spin coating.

The emission layer 223 is disposed inside the opening of the bank layer BKL, and the second electrode 225 is disposed on the emission layer 223. The second electrode 225 may be integrally formed (or unitary) to correspond to the light-emitting diodes LED1, LED2, and LED3 as a common electrode.

An upper layer 250 including an organic material may be formed on the second electrode 225. The upper layer 250 may be a layer provided to protect the second electrode 225 and increase light extraction efficiency. The upper layer 250 may include an organic material having a refractive index that is higher than a refractive index of the second electrode 225. In an alternative embodiment, the upper layer 250 may be provided by stacking layers having different refractive indices. In an embodiment, the upper layer 250 may be provided by stacking a relatively high refractive index layer/a relatively low refractive index layer/a relatively high refractive index layer, for example. At this time, the refractive index of the relatively high refractive index layer may be 1.7 or more and the refractive index of the relatively low refractive index layer may be 1.3 or less.

The upper layer 250 may further include LiF. In an alternative embodiment, the upper layer 250 may further include an inorganic insulating material, such as silicon oxide (SiO₂) or silicon nitride (SiNx).

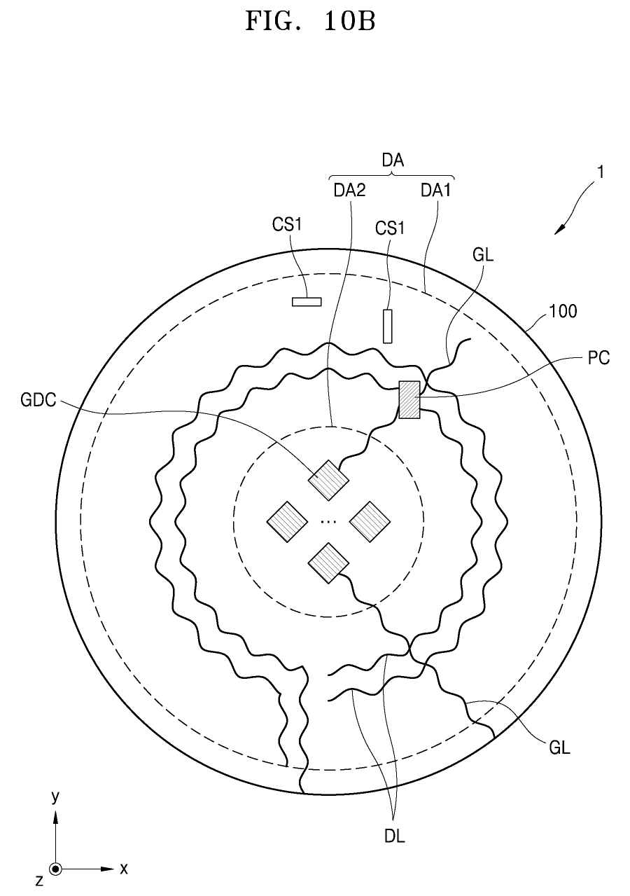

FIGS. 10A and 10B are plan views illustrating an embodiment of a portion of a display device according to the disclosure. Specifically, FIGS. 10A and 10B illustrate an arrangement relationship of a gate line and a data line.

Referring to FIG. 10A, a substrate 100 of a display device 1 includes a first display area DA1 and a second display area DA2 surrounded by the first display area DA1. The second display area DA2 may be disposed in the central portion of the substrate 100. A first opening area CS1 may be provided in the first display area DA1, and an opening area may not be in the second display area DA2. Accordingly, the modulus of the second display area DA2 may be provided to be greater than the modulus of the first display area DA1.

A gate driving circuit GDC may be disposed in the second display area DA2 and may provide scan signals and/or emission control signals through gate lines GL to pixel driving circuits PC disposed in the first display area DA1.

In the illustrated embodiment, the gate line GL connected to the gate driving circuit GDC may extend from the second display area DA2 to the edge of the first display area DA1. A plurality of gate lines GL may be provided, and the plurality of gate lines GL may be disposed radially from the second display area DA2 disposed in the central portion of the substrate 100 to the edge of the substrate 100.

The data line DL may be disposed to cross the gate line GL. Accordingly, the data line DL may be disposed to at least partially surround the second display area DA2.

The gate line GL and the data line DL may be connected to the pixel driving circuit PC to respectively transmit the scan signal and the data signals thereto.

In FIG. 10A, the gate line GL is illustrated as a straight line and the data line DL is illustrated as a circle, but the disclosure is not limited thereto.

As in FIG. 10B, the gate line GL and the data line DL may be provided in a curved shape. In an embodiment, the gate line GL and the data line DL may be provided in a serpentine shape or a zigzag shape, for example. Since the first display area DA1 has the first opening area CS1, the gate line GL and the data line DL may be disposed to bypass the first opening area CS1. That is, the plurality of gate lines GL may be disposed radially from the central portion to the edge of the display area DA, and each of the gate lines GL may be provided in a serpentine shape. Similarly, the data lines DL may be disposed to surround the second display area DA2, and each of the data lines DL may be provided in a serpentine shape.

The display device 1 in the embodiments described above may be used in various electronic devices capable of providing images. Here, the electronic device refers to a device that has a function capable of providing a predetermined image by electricity.

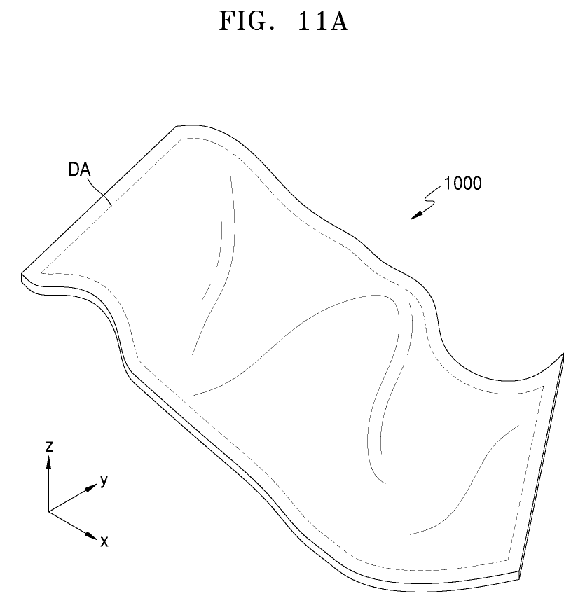

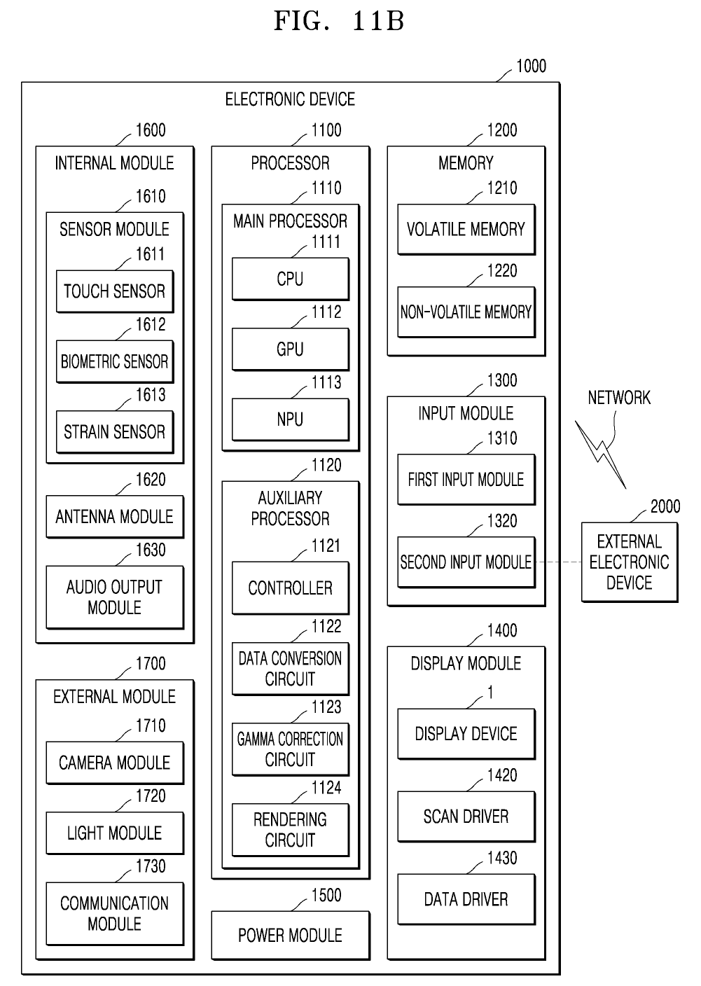

FIG. 11A is a perspective view schematically illustrating an embodiment of an electronic device 1000 including a display device, according to the disclosure, and FIG. 11B is a block diagram schematically illustrating an embodiment of an electronic device 1000 including a display device 1, according to the disclosure.

Referring to FIG. 11A, the electronic device 1000 may be freely transformed three-dimensionally and provide a three-dimensional image surface through a display area DA. The expression that the electronic device 1000 is freely transformed three-dimensionally is distinguished from the operation of the electronic device having a rollable display device, such as a case where a portion of the rolled display area is visible to the user and then the entirety of the

display area is visible to the user while the rolled display area is unrolled (or a case where the entirety of the unrolled display area is visible to the user and then a portion of the display area is visible to the user while the display area is rolled). The electronic device 1000 in embodiments of the disclosure may be deformed such that the area of the entirety of the display area DA increases or decreases again as the electronic device 1000 is deformed in the x direction, the y direction, and/or the z direction.

Referring to FIG. 11B, the electronic device 1000 may include a processor 1100, a memory 1200, an input module 1300, a display module 1400, a power module 1500, an internal module 1600, and an external module 1700. In an embodiment, at least one of the components described above may be omitted from the electronic device 1000, or one or more other components may be added to the electronic device 1000. In an embodiment, some of the components described above (e.g., the internal module 1600) may be integrated into another component (e.g., the display module 1400).

The processor 1100 may execute software to control at least one other component (e.g., a hardware or software component) of the electronic device 1000 connected to the processor 1100 and perform various data processing or operations. In an embodiment, as at least part of data processing or operations, the processor 1100 may store commands or data received from another component (e.g., the input module 1300, a sensor module 1610, or a communication module 1730) in a volatile memory 1210, process the commands or data stored in the volatile memory 1210, and store resulting data in a non-volatile memory 1220.

The processor 1100 may include a main processor 1110 and an auxiliary processor 1120. The main processor 1110 may include at least one of a CPU (central processing unit) 1111 and an application processor (“AP”). The main processor 1110 may further include at least one of a graphics processing unit (“GPU”) 1112, a communication processor (“CP”), and an image signal processor (“ISP”). The main processor 1110 may further include a neural processing unit (“NPU”) 1113. The neural processing unit is a processor specialized in processing an artificial intelligence model, and the artificial intelligence model may be generated through machine learning. The artificial intelligence model may include a plurality of artificial neural network layers. The artificial intelligence model may be one of a deep neural network (“DNN”), a convolutional neural network (“CNN”), a recurrent neural network (“RNN”), a restricted Boltzmann machine (“RBM”), a deep belief network (“DBN”), a bidirectional recurrent deep neural network (“BRDNN”), a deep

Q-network, or a combination of two or more thereof, but the disclosure is not limited to the above example. The artificial intelligence model may additionally or alternatively include a software structure in addition to the hardware structure. At least two of the processing units and processors described above may be implemented as a single integrated component (e.g., a single chip), or the processing units and processors described above may be implemented as independent components (e.g., a plurality of chips).

The auxiliary processor 1120 may include a controller 1121. The controller 1121 may include an interface conversion circuit and a timing control circuit. The controller 1121 receives an image signal from the main processor 1110, converts the data format of the image signal to conform to the interface specifications with the display module 1400, and outputs the image data. The controller 1121 may output various control signals desired to drive the display module 1400.

The auxiliary processor 1120 may further include a data processing circuit, such as a data conversion circuit 1122, a gamma correction circuit 1123, or a rendering circuit 1124. The data conversion circuit 1122 may receive image data from the controller 1121, compensate for the image data so that the image is displayed at a desired luminance according to characteristics of the electronic device 1000 or a user's settings, or convert the image data so as to reduce power consumption or compensate for afterimages. The gamma correction circuit 1123 may convert image data or gamma reference voltages so that the image displayed on the electronic device 1000 has desired gamma characteristics. The rendering circuit 1124 may receive image data from the controller 1121 and render the image data by taking into account the pixel layout of the display device 1 applied to the electronic device 1000. At least one of the data conversion circuit 1122, the gamma correction circuit 1123, and the rendering circuit 1124 may be integrated into another component (e.g., the main processor 1110 or the controller 1121. In an embodiment, the auxiliary processor 1120 may be integrated into a data driver 1430.

The memory 1200 may store various data used by at least one component of the electronic device 1000 (e.g., the processor 1100 or the sensor module 1610) and input data or output data for commands related thereto. The memory 1200 may include at least one of the volatile memory 1210 and the non-volatile memory 1220.

The input module 1300 may receive commands or data to be used in the components of the electronic device 1000 (e.g., the processor 1100, the sensor module 1610, or the audio output module 1630) from the outside of the electronic device 1000 (e.g., a user or an external electronic device 2000).

The input module 1300 may include a first input module 1310 to which commands or data are input from the user and a second input module 1320 to which commands or data are input from the external electronic device 2000.

The first input module 1310 may include a microphone, a mouse, a keyboard, or a pen (e.g., a passive pen or an active pen). The first input module 1310 may include a touch input means or a mechanical input means, such as a button, a dome switch, a jog wheel, or a jog switch, which is disposed on the rear or side surface of the electronic device 1000. The touch input means may include a touch screen layer of the display device 1.

The second input module 1320 may be connected, in a wired or wireless manner, to various types of external electronic devices 2000 connected to the electronic device 1000. In an embodiment, the second input module 1320 may include an HDMI (high definition multimedia interface), a USB (universal serial bus) interface, an SD card interface, or an audio interface. The second input module 1320 may include a connector which enables the electronic device 1000 to be physically connectable to the external electronic device 2000, e.g., an HDMI connector, a USB connector, an SD card connector, or an audio connector (e.g., a headphones connector). In response to the connection of the external electronic device 2000 to the second input module 1320, the electronic device 1000 may perform appropriate control related to the connected external electronic device 2000.

The display module 1400 may provide visual information to the user. The display module 1400 may include the display device 1, a scan driver 1420, and the data driver 1430.

The display device 1 may display (output) information processed by the electronic device 1000. The display device 1 may display execution screen information of an application driven by the electronic device 1000, or UI (user interface) or GUI (graphic user interface) information based on the execution screen information.

The scan driver 1420 may be disposed (e.g., mounted) on the display device 1 as a driving chip. In an alternative embodiment, the scan driver 1420 may be formed directly on the display device 1. In an embodiment, the scan driver 1420 may include an amorphous silicon (“AGS”) TFT gate driver circuit, a low temperature polycrystalline silicon (“LTPS”) TFT gate driver circuit, or an oxide semiconductor gate (“OSG”) TFT gate driver circuit, which is embedded in the display device 1, for example. The scan driver 1420 may receive a control signal from the controller 1121 and output scan signals to the display device 1 in response to the control signal.

The display device 1 may further include an emission control driver. The emission control driver outputs an emission control signal to the display device 1 in response to the control signal received from the controller 1121. The emission control driver may be formed separately from the scan driver 1420 or may be integrated into the scan driver 1420.

The data driver 1430 receives a control signal from the controller 1121, converts image data into data voltages of analog voltage forms in response to the control signal, and then outputs the data voltages to the display device 1.

The data driver 1430 may be integrated with some components of the auxiliary processor 1120. In an embodiment, the data driver 1430 may be provided as a timing controller embedded driver integrated circuit (“IC”) including the controller 1121, for example.

The power module 1500 may supply power to the components of the electronic device 1000. The power module 1500 may include a battery which is charged with a power supply voltage. In addition, the power module 1500 may include a connection port, and the connection port may be included in the second input module 1320 to which an external charger that supplies power for charging the battery is connected. In an alternative embodiment, the power module 1500 may include a wireless power transmission/reception member so as to enable wireless charging of the battery. The wireless power transmission/reception member may include a plurality of coil-type antenna radiators. The power module 1500 may include a power management integrated circuit (“PMIC”). The PMIC may supply optimized power to the respective components of the electronic device 1000.

The electronic device 1000 may further include the internal module 1600 and the external module 1700. The internal module 1600 may include the sensor module 1610, the antenna module 1620, and the audio output module 1630. The external module 1700 may include a camera module 1710, a light module 1720, and/or the communication module 1730.

The sensor module 1610 may include a touch sensor driving unit and touch electrodes of the touch screen layer of the display device 1. The sensor module 1610 may sense an input by a user's body or an input by a pen and may generate an electrical signal or a data value corresponding to the input. The sensor module 1610 may include at least one of a touch sensor 1611, a biometric sensor 1612, and a strain sensor 1613.

The touch sensor 1611 may generate a data value corresponding to coordinate information of the input by the user's body (e.g., a finger, etc.) or the input by the pen. The touch sensor 1611 may generate, as the data value, a change of amount in electrostatic capacitance, a change of amount in pressure, or a change of amount in electromagnetism due to the input.

The biometric sensor 1512 may generate a data value that recognizes a part of the user's body (e.g., a fingerprint, an iris, a face, etc.) or generate a data value corresponding to body information (e.g., blood pressure, moisture, a heart rate, a body composition, etc.). The biometric sensor 1512 may use an optical method, an ultrasonic method, or a capacitive method.

The strain sensor 1613 may include layers, patterns, or wirings, of which the measurable physical quantities change due to the stretching and recovery of the display device 1. In an embodiment, the strain sensor 1613 may include wirings, of which the resistance and/or capacitance change due to the stretching and recovery of the display device 1, for example. In another embodiment, the strain sensor 1613 may include an optical layer or an optical pattern, of which the transmittance and/or reflectivity change due to the stretching and recovery of the display device 1.

Based on the change in physical quantities due to the stretching and recovery of the display device 1, which is measured by the strain sensor 1613, the electronic device 1000 may improve the image quality of the image implemented in the display device 1 or may control the display device 1. The control operation of the display device 1 may include an operation of displaying an operation image for protecting the display device 1, cutting off a voltage for driving the display device 1, or stopping a stretching and recovery operation of the display device 1, for example.

In an embodiment, at least one of the touch sensor 1611, the biometric sensor 1612, a digitizer, and the strain sensor 1613 may be embedded into the display device 1. In an embodiment, at least one of the touch sensor 1611, the biometric sensor 1612, and the strain sensor 1613 may be formed through a process that is continuous with the process of forming the pixel driving circuits and/or the light-emitting elements of the display device 1, for example. Due to this, the display device 1 may function as one of the input modules 1300 that provide an input interface between the electronic device 1000 and the user and may also function as the display module 1400 that provides an output interface between the electronic device 1000 and the user.

In an embodiment, at least two of the touch sensor 1611, the biometric sensor 1612, and the strain sensor 1613 may be integrated into a single sensing panel through the same process. In an embodiment, the sensing panel may be disposed between the display device 1 and a window cover disposed on the front surface of the display device 1, but the disclosure is not limited thereto.

The antenna module 1620 may include one or more antennas that transmit signals or power to the outside or receive signals or power from the outside. In an embodiment, the communication module 1730 may transmit or receive signals to and from an external electronic device through an antenna suitable for a communication scheme. An antenna pattern of the antenna module 1620 may be integrated into one component of the display module 1400 (e.g., the display device 1) or the input sensor.

The audio output module 1630 is a device for outputting an audio signal to the outside of the electronic device 1000 and may output audio data received from the communication module 1730 or stored in the memory 1200 in a call signal reception mode or call mode, a recording mode, a voice recognition mode, a broadcast reception mode, etc. The audio output module 1630 may output an audio signal related to the function performed in the electronic device 1000 (e.g., a call signal reception sound, a message reception sound, etc.). The audio output module 1630 may include a receiver and a speaker. At least one of the receiver and the speaker may be a sound generation device that is attached to the rear surface of the display device 1 and vibrates the display device 1 to output sound. The sound generation device may be a piezoelectric element or a piezoelectric actuator that contracts and expands in response to an electrical signal, or may be an exciter that generates a magnetic force by a voice coil and vibrates the display device 1.

The camera module 1710 may capture still images and moving images. In an embodiment, the camera module 1710 may include one or more lenses, image sensors, or image signal processors. The camera module 1710 may further include an infrared camera capable of measuring the presence or absence of the user, the user's location, the user's line of sight, or the like.

The light module 1720 may output a signal to notify the occurrence of an event by light from a light source or provide light so as to obtain an image. Here, embodiments of the occurrence of the event may include message reception, call signal reception, missed call, alarm, schedule reminder, email reception, and notification of battery charge capacity information. The light module 1720 may include a light-emitting diode or a xenon lamp. The light module 1720 may emit light of one or more colors to the front or back of the electronic device 1000. The light module 1720 may operate in conjunction with the camera module 1710 or may operate independently.

The communication module 1730 may support establishment of a wired or wireless communication channel between the electronic device 1000 and the external electronic device 2000 and may support performance of communication through the established communication channel. The communication module 1730 may include one or all of a wireless communication module, such as a cellular communication module, a short-range wireless communication module, or a GNSS (global navigation satellite system) communication module, and a wired communication module, such as a LAN (local area network) communication module or a power line communication module. The communication module 1730 may transmit and receive wireless signals on the Internet by at least one of wireless LAN (“WLAN”), Wireless-Fidelity (“Wi-Fi”), Wi-Fi Direct, and digital living network alliance (“DLNA”). In addition, the communication module 1730 may support short-range communication by at least one of Bluetooth, Radio Frequency Identification (“RFID”), Infrared Data Association (“IrDA”), Ultra Wideband (“UWB”), ZigBee, Near Field Communication (“NFC”), Wi-Fi, Wi-Fi Direct, and Wireless USB. Various types of the communication module 1730 described above may be implemented as a single chip or may be implemented as separate chips.

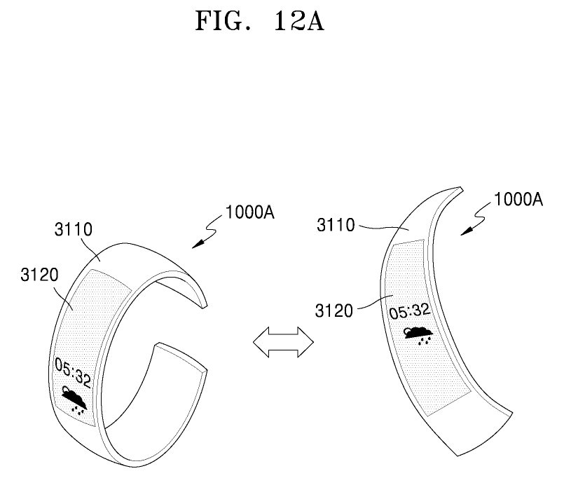

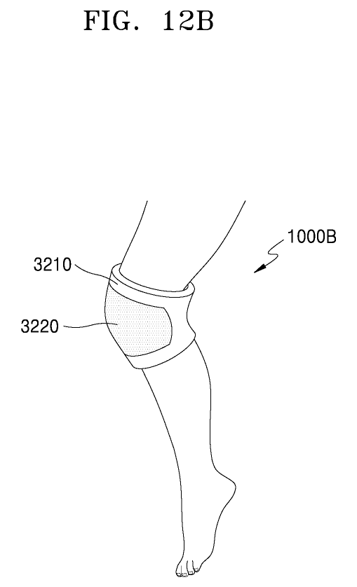

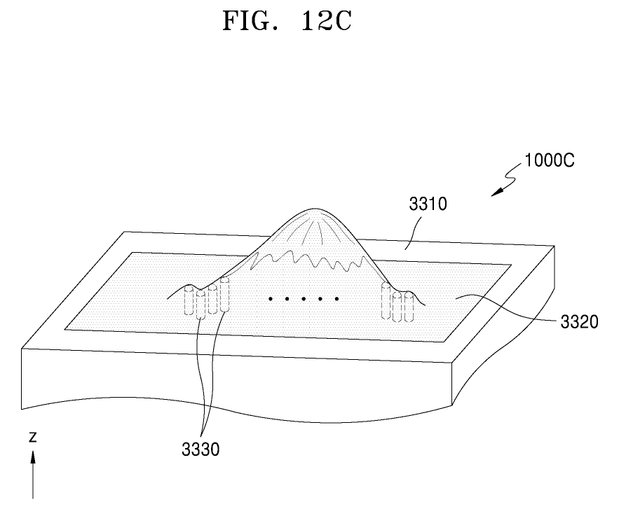

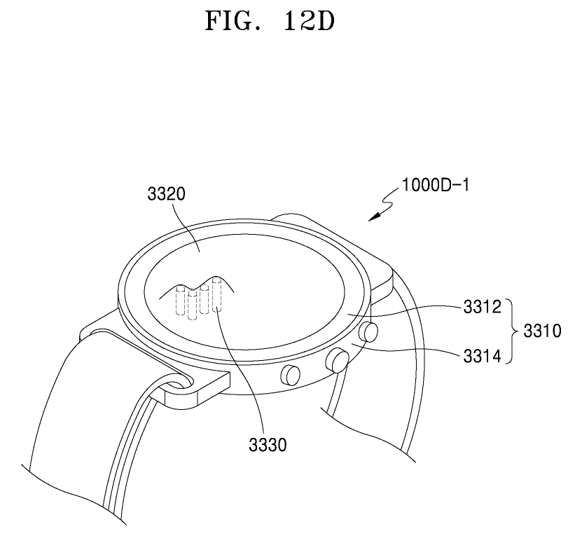

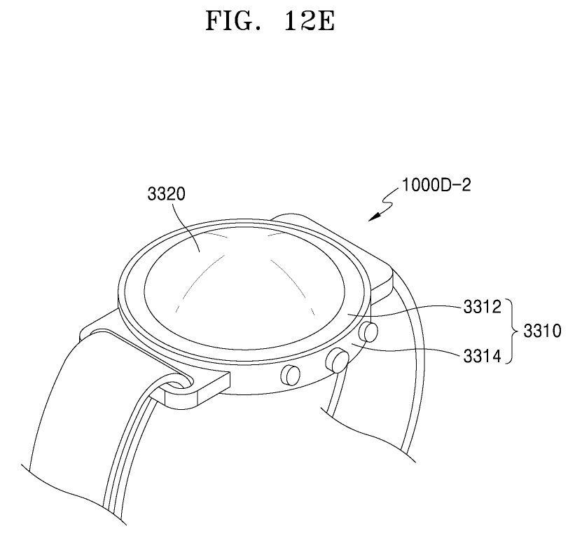

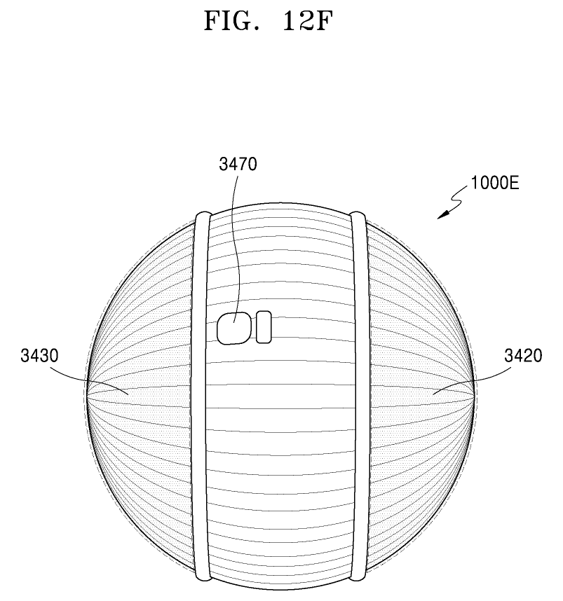

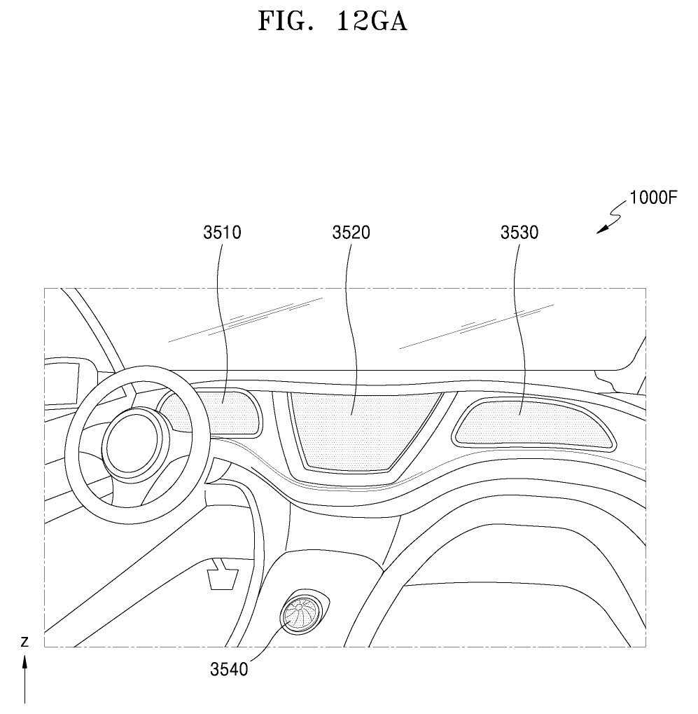

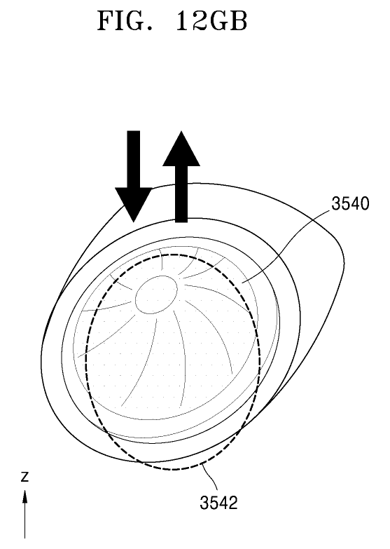

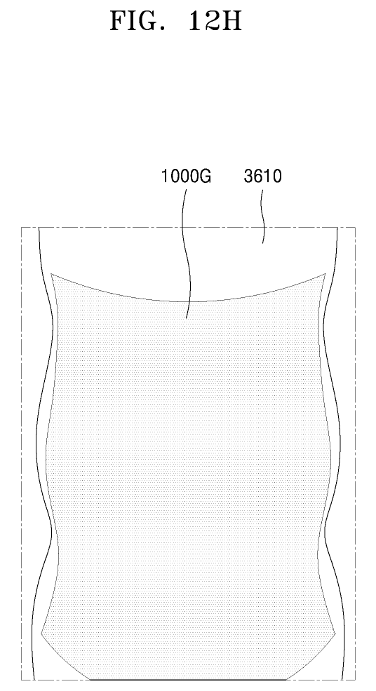

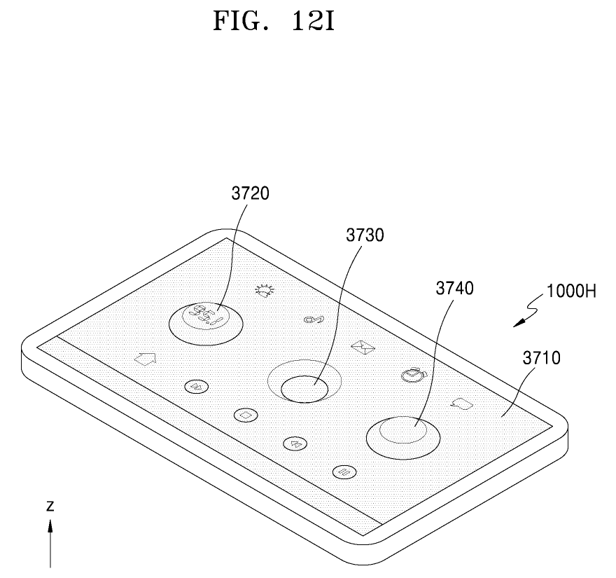

FIGS. 12A to 12D are respectively perspective views schematically illustrating embodiments of an electronic device including a display device, according to the disclosure.

Referring to FIG. 12A, the display device in an embodiment of the disclosure may be used in a wearable electronic device 1000A that is wearable on a part of a user's body. The wearable electronic device 1000A may include a body portion 3110 and a display unit 3120 provided in the body portion 3110. The display device in embodiments of the disclosure may be used as the display unit 3120 of the wearable electronic device 1000A. As illustrated in FIG. 12A, the wearable electronic device 1000A may be modified. In an embodiment, the wearable electronic device 1000A may be used as a smart watch or a smartphone according to a user’s choice.

FIG. 12B illustrates a medical electronic device 1000B. In an embodiment, the medical electronic device 1000B may include a body portion 3210 and a light-emitting unit 3220. The display device in embodiments of the disclosure may be used as the light-emitting unit 3220 of the medical electronic device 1000B. The light-emitting unit 3220 may emit light of a predetermined wavelength band (e.g., infrared light, visible light, etc.) to a patient's body. In an embodiment, the body portion 3210 may have a stretchable fiber material and may have a structure that is wearable on the body of the user.

FIG. 12C illustrates an educational electronic device 1000C. In an embodiment, the educational electronic device may include a display unit 3320 provided in a body portion 3310. The display unit 3320 may use the display devices according to the disclosure. The display unit 3320 may provide images, such as a sea with waves, a mountain covered with snow, or a volcano with flowing lava, and in this case, the display unit 3320 may extend in the height direction (e.g., the z direction) to reflect the height of the waves, the mountain, or the volcano. In some embodiments, a portion of the display unit 3320 may show the movement of lava in three dimensions by sequentially changing the height in the direction along which the lava flows. The educational electronic device 1000C may include a plurality of pins (or stroke portions, 3330) disposed on the back surface of the display unit 3320 so that the display unit 3320 is stretched in the height direction. As the pins 3330 move in the third direction (e.g., the z direction or the -z direction), the image displayed on the display unit 3320 may be implemented to have a three-dimensional height. Although FIG. 12C illustrates the educational electronic device 1000C, the use of the educational electronic device 1000C is not limited as long as the educational electronic device 1000C provides predetermined image information.

FIGS. 12D and 12E illustrate the use of the display device in wearable electronic devices 1000D-1 and 1000D-2, such as smart watches.

In an embodiment, since the display device corresponding to the display unit 3320 of the electronic device 1000D-1, as illustrated in FIG. 12D, is three-dimensionally stretchable, the display device may provide a variety of haptic information to the user as well as visual information through an image. In an embodiment, the electronic device 1000D-1 may provide haptic information, such as Braille display for the visually impaired or tactile stimulation linked to an image, by a plurality of pins (or stroke portions, 3330) disposed below the display unit 3320. Since the display device forming the display unit 3320 is three-dimensionally stretchable, the display device may provide the aforementioned haptic information to the user. The electronic device 1000D-1 may include a body portion 3310 including a housing 3314 in which the display device forming the display unit 3320 and the pins (or the stroke portions, 3330) are accommodated, and a frame 3312 that may be coupled to the housing 3314 with the display device therebetween. In some embodiments, the frame 3312 may be formed integrally with the housing 3314.

The electronic device 1000D-2 of FIG. 12E may include a body portion 3310 and a display unit 3320 accommodated in the body portion 3310 and capable of providing visual information,

as illustrated in FIG. 12D. In some embodiments, since the display device corresponding to the display unit 3320 is three-dimensionally stretchable, the display device may include a dome-shaped display unit 3320. In an embodiment, a display device may be assembled on a dome-shaped body frame in a process of manufacturing the electronic device 1000D-2, and at this time, the display device is three-dimensionally stretchable and thus may be assembled in a state of being stretched along a shape of a hemispherical body frame.

FIG. 12F illustrates that an electronic device 1000E in an embodiment of the disclosure includes a robot. The robot may recognize movement or objects by a camera module 3470 and may display predetermined images to a user on display units 3420 and 3430.

In some embodiments, since the display devices in an embodiment of the disclosure may be stretched in various directions, as described above, the display devices may be assembled into a body frame having a hemispherical shape, and accordingly, the robot may include the hemispherical display units 3420 and 3430.

FIG. 12GA illustrates a vehicle display device 1000F as an electronic device according to the disclosure, and FIG. 12GB is an enlarged view of a portion of FIG. 12GA. The vehicle display device 1000F may include a cluster 3510, a center information display (“CID”) 3520, and/or a co-driver display 3530. Since the display device in an embodiment of the disclosure may be stretched in various directions, the display device may be used in the cluster 3510, the CID 3520, and/or the co-driver display 3530, regardless of the shape of the internal frame of the vehicle.

Although FIG. 12GB illustrates that the cluster 3510, the CID 3520, and/or the co-driver display 3530 are separated from each other, the disclosure is not limited thereto. In another embodiment, two or more selected from the cluster 3510, the CID 3520, and the co-driver display 3530 may be integrally connected to each other.

In some embodiments, the vehicle display device 1000F may include a button 3540 capable of expressing a predetermined image. Referring to the enlarged view of FIG. 12GB, the hemispherical button 3540 may include an object 3542 that provides the feeling of using the button while moving in the z direction or the -z direction, and a display device disposed on the object 3542. In some embodiments, when the object 3542 has a three-dimensionally round surface, the display device may also have a three-dimensionally round surface.

FIG. 12H illustrates that the electronic device in an embodiment of the disclosure is an advertising or exhibition electronic device 1000G. In some embodiments, the advertising or exhibition electronic device 1000G may be installed on a fixed structure 3610, such as a wall or a pillar. When the structure 3610 includes an uneven surface as illustrated in FIG. 12H, the advertising or exhibition electronic device 1000G may also be disposed along the uneven surface of the structure 3610. In some embodiments, the advertising or exhibition electronic device 1000G may be installed on the structure 3610 by a heat-shrinkable film or the like.

FIG. 12I illustrates that an electronic device 1000H in an embodiment of the disclosure is a controller. The controller may include an image-type button. In an embodiment, the controller may include first to third button areas 3720, 3730, and 3740 in which a partial area of a display unit 3710 protrudes in the z direction or protrudes in the -z direction (or is recessed in the z direction), for example. In some embodiments, the first and third button areas 3720 and 3740 may protrude in the z direction, and the second button area 3730 may protrude in the -z direction (or may be recessed in the z direction).

The disclosure has been described with reference to the embodiments illustrated in the drawings, but this is only an illustrative embodiment, and it will be understood by those of ordinary skill in the art that various modifications and other equivalent embodiments are possible. Therefore, the true technical protection scope of the disclosure should be defined by the technical spirit of the appended claims.

What is claimed is:

1. A display device comprising:
a substrate including:
a first display area; and
a second display area surrounded by the first display area;
a plurality of first light-emitting diodes and a plurality of first pixel driving circuits disposed in the first display area; and
a gate driving circuit which is disposed in the second display area and provides a scan signal to the plurality of first pixel driving circuits,
wherein a shape of the second display area in the substrate is different from a shape of the first display area.

2. The display device of claim 1, wherein the first display area comprises a plurality of first island portions separated by a plurality of first opening areas passing through the substrate, and the second display area comprises one second island portion in which the substrate is continuously disposed.

3. The display device of claim 2, wherein the substrate further comprises a middle area disposed between the first display area and the second display area,
the middle area comprises a plurality of third island portions separated by a plurality of third opening areas passing through the substrate, and
a shape of a third opening area among the plurality of third island portions is different from a shape of a first opening area among the plurality of first opening areas.

4. The display device of claim 3, further comprising a third light-emitting diode disposed in the middle area,
wherein the third light-emitting diode is connected to one of the plurality of first pixel driving circuits disposed in the first display area.

5. The display device of claim 1, further comprising a second light-emitting diode disposed in the second display area and a second pixel driving circuit which drives the second light-emitting diode,
wherein the second light-emitting diode comprises a second-1 light-emitting diode which overlaps the second pixel driving circuit and a second-2 light-emitting diode which overlaps the gate driving circuit.

6. The display device of claim 5, wherein the second pixel driving circuit is disposed closer to the first display area than the gate driving circuit.

7. The display device of claim 1, further comprising a plurality of scan lines which are connected to the gate driving circuit and transmit the scan signal,
wherein the plurality of scan lines are disposed radially from the second display area to an outside of the first display area.

8. The display device of claim 7, further comprising a plurality of data lines crossing the plurality of scan lines,
wherein the plurality of data lines are disposed to surround the second display area.

9. The display device of claim 8, wherein the plurality of data lines and the plurality of scan lines are disposed in a curved shape.

10. A display device comprising:
a substrate including a display area including:
a first display area; and
a second display area surrounded by the first display area;
a plurality of first light-emitting diodes and a plurality of first pixel driving circuits disposed in the first display area;
a gate driving circuit which is disposed in the second display area and provides a scan signal to the plurality of first pixel driving circuits; and
a plurality of second light-emitting diodes disposed in the second display area and at least partially overlapping the gate driving circuit.

11. The display device of claim 10, wherein the second display area is disposed in a center of the display area.

12. The display device of claim 10, further comprising a plurality of second pixel driving circuits which are disposed in the second display area and drive the plurality of second light-emitting diodes,
wherein the plurality of second light-emitting diodes comprise a plurality of second-1 light-emitting diodes which overlap the plurality of second pixel driving circuits and a plurality of second-2 light-emitting diodes which overlap the gate driving circuit.

13. The display device of claim 12, wherein the plurality of second pixel driving circuits are disposed closer to the first display area than the gate driving circuit.

14. The display device of claim 10, wherein the first display area comprises a plurality of first island portions separated by a plurality of first opening areas passing through the substrate, and the second display area comprises one second island portion in which the substrate is continuously disposed.

15. The display device of claim 10, further comprising a plurality of scan lines which are connected to the gate driving circuit and transmit the scan signal,
wherein the plurality of scan lines are disposed radially from the second display area to an outside of the first display area.

16. An electronic device comprising a display device, wherein the display device comprises:
a substrate including:
a display area including:
a first display area; and
a second display area surrounded by the first display area;
a plurality of first light-emitting diodes and a plurality of first pixel driving circuits disposed in the first display area;
a gate driving circuit which is disposed in the second display area and provides a scan signal to the plurality of first pixel driving circuits; and
a plurality of second light-emitting diodes disposed in the second display area and at least partially overlapping the gate driving circuit.

17. The electronic device of claim 16, wherein the second display area is disposed in a center of the display area.

18. The electronic device of claim 16, further comprising a plurality of second pixel driving circuits which are disposed in the second display area and drive the plurality of second light-emitting diodes,
wherein the plurality of second light-emitting diodes comprise a plurality of second-1 light-emitting diodes which overlap the plurality of second pixel driving circuits and a plurality of second-2 light-emitting diodes which overlap the gate driving circuit.

19. The electronic device of claim 18, wherein the plurality of second pixel driving circuits are disposed closer to the first display area than the gate driving circuit.

20. The electronic device of claim 16, wherein the first display area comprises a plurality of first island portions separated by a plurality of first opening areas passing through the substrate, and the second display area comprises one second island portion in which the substrate is continuously disposed.
